(19) United States
(12) Patent Application Publication
(10) Pub. No.: US 2026/0344091 A1
(43) Pub. Date: Oct. 29, 2026

(54) FRONTSIDE TRENCH ISOLATION STRUCTURE FOR COUPLING BACKSIDE TRENCH ISOLATION STRUCTURE TO FRONTSIDE INTERCONNECT STRUCTURE

(71) Applicant: Taiwan Semiconductor Manufacturing Company, Ltd., Hsinchu (TW)

(72) Inventors: Ting-Tso Yeh, Kaohsiung City (TW); U-Ting Chen, Wanluan Township (TW); Shu-Ting Tsai, Kaohsiung City (TW); Cheng Jui Chung, Hsinchu (TW); Shyh-Fann Ting, Tainan City (TW)

(21) Appl. No.: 19/734,319

(22) Filed: Jul. 8, 2026

Related U.S. Application Data
(63) Continuation of application No. 18/958,045, filed on Nov. 25, 2024.

(51) Int. Cl. H10F 39/00; H10F 39/12

(52) U.S. Cl. CPC H10F 39/807; H10F 39/011; H10F 39/199; H10F 39/811

(57) ABSTRACT

An integrated chip including a first semiconductor substrate having a frontside and a backside opposite the frontside. A photodetector is within the first semiconductor substrate. A backside deep trench isolation (DTI) structure includes a conductive backside isolation layer and a dielectric backside isolation layer extending into the first semiconductor substrate from the backside toward the frontside and extending between the photodetector and neighboring photodetectors to isolate the photodetector from the neighboring photodetectors. The dielectric backside isolation layer is between the conductive backside isolation layer and the first semiconductor substrate. A first interconnect structure includes a first plurality of conductive interconnects along the frontside of the first semiconductor substrate. A conductive frontside DTI structure extends from the first interconnect structure to the conductive backside isolation layer and couples the conductive backside isolation layer to the first interconnect structure.

### REFERENCE TO RELATED APPLICATION

This Application is a Continuation of U.S. Application number 18/958,045, filed on Nov. 25, 2024, the contents of which are hereby incorporated by reference in their entirety.

### BACKGROUND

Many modern day electronic devices contain image sensors. Image sensors may be backside illuminated sensors or frontside illuminated sensors. Backside illuminated sensors can increase the amount of light captured by the sensor while frontside illuminate sensors can have a greater response uniformity. In many image sensors, deep trench isolation (DTI) structures are used to provide electrical and/or optical isolation between pixels of the image sensor.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of some embodiments of an integrated chip including a frontside deep trench isolation (DTI) structure which couples an interconnect structure to a backside DTI structure.

FIG. 2 illustrates a top view of some embodiments of the integrated chip of FIG. 1.

FIGS. 3-7 illustrate cross-sectional views of some other embodiments of the integrated chip of FIG. 1.

FIGS. 8-10 illustrate cross-sectional views of various embodiments of the backside DTI structure and the frontside DTI structure of any of FIGS. 1-7.

FIG. 11 and FIG. 12 illustrate cross-sectional views of some other embodiments of the integrated chips of FIGS. 4-6.

FIGS. 13-36 illustrate cross-sectional views of some embodiments of a method for forming an integrated chip including a frontside DTI structure which couples an interconnect structure to a backside DTI structure.

FIG. 37 illustrates a flow diagram of some embodiments of a method for forming an integrated chip including a frontside deep trench isolation structure which couples an interconnect structure to a backside deep trench isolation structure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

An integrated chip includes an image sensor. The image sensor includes photodetectors along a semiconductor substrate. An interconnect structure is disposed along a frontside of the semiconductor substrate. A backside deep trench isolation (DTI) structure extends into the semiconductor substrate from a backside of the substrate toward the frontside of the semiconductor substrate and between the photodetectors to electrically and/or optically isolate the photodetectors from each other. In some integrated chips, the backside DTI structure is formed by etching the semiconductor substrate from the backside of the semiconductor substrate to form a backside trench in the semiconductor substrate and filling the backside trench with a dielectric isolation layer. In some cases, etching the semiconductor substrate to form the backside trench may form defects (e.g., point defects, dangling bonds, or the like) along the sidewalls of the semiconductor substrate that delimit the backside trench. These defects may increase a dark current in the photodetectors which may increase noise and reduce the performance of the image sensor.

In various embodiments of the present disclosure, the backside DTI structure further includes a conductive isolation layer over the dielectric isolation layer in the backside trench, and a conductive frontside DTI structure coupling the interconnect structure to the conductive isolation layer of the backside DTI structure. By coupling the interconnect structure to the conductive isolation layer of the backside DTI structure with the conductive frontside DTI structure, a bias can be provided to the conductive isolation layer of the backside DTI structure through the conductive frontside DTI structure. Applying the bias to the backside DTI structure can reduce the dark current caused by the backside trench defects. Thus, a performance of the image sensor may be improved.

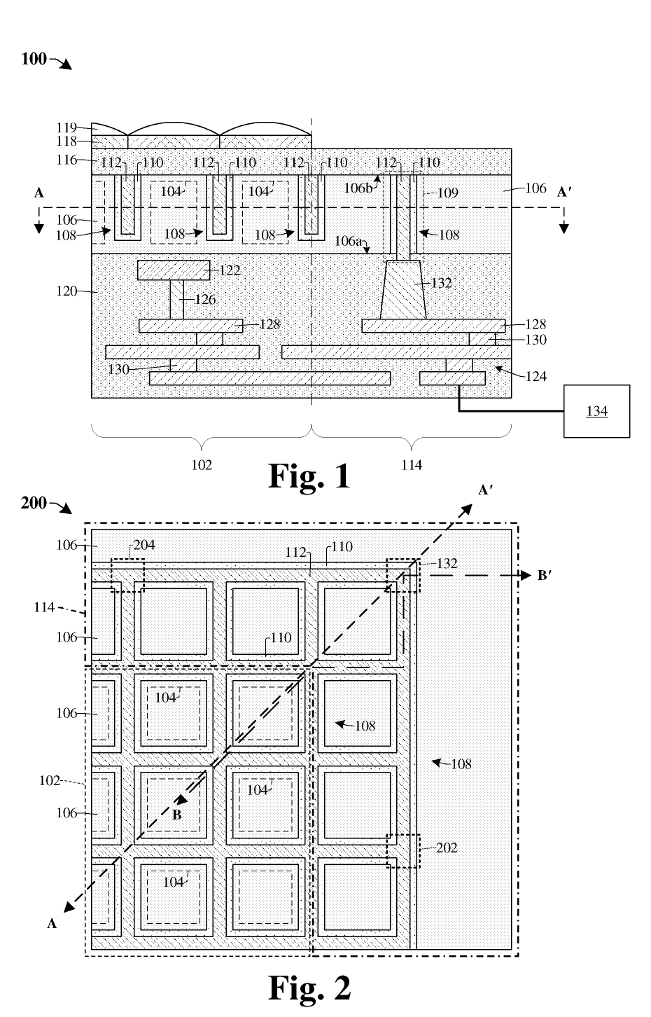

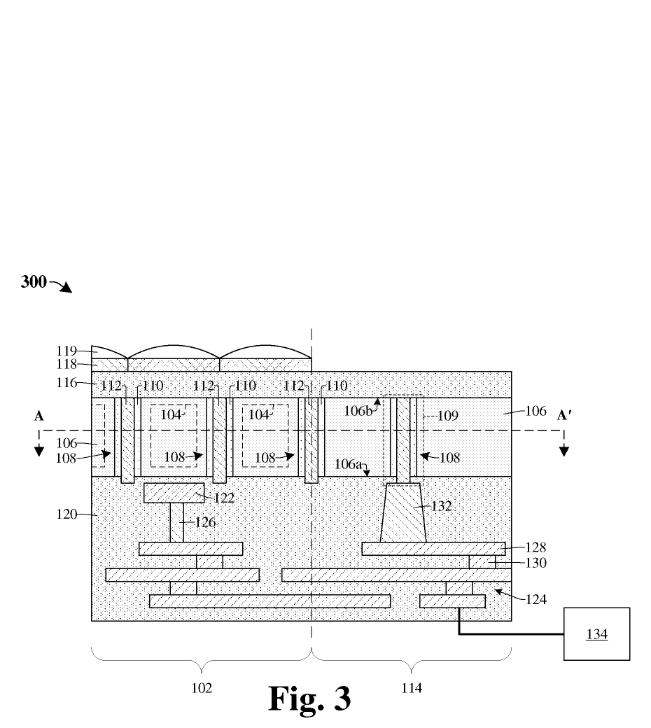

FIG. 1 illustrates a cross-sectional view 100 of some embodiments of an integrated chip including a frontside deep trench isolation (DTI) structure 132 which couples an interconnect structure 124 to a backside DTI structure 108. FIG. 2 illustrates a top view 200 of some embodiments of the integrated chip of FIG. 1. In some embodiments, section line A-A′ of FIG. 1 corresponds to section line A-A′ of FIG. 2.

Referring to FIG. 1 and FIG. 2, the integrated chip includes a first semiconductor substrate 106. An active pixel region 102 of the integrated chip includes a plurality of photodetectors 104 (e.g., photodiodes or the like) laterally spaced apart along the first semiconductor substrate 106.

The backside DTI structure 108 fills a backside deep trench (not labeled) in the first semiconductor substrate 106. The backside DTI structure 108 extends between the photodetectors 104 in a grid-like layout along the backside 106b of the first semiconductor substrate 106 to electrically and/or optically isolate the photodetectors 104 form each other. The backside DTI structure 108 includes a dielectric backside isolation layer 110 and a conductive backside isolation layer 112. The conductive backside isolation layer 112 is over and between sidewalls of the dielectric backside isolation layer 110. The dielectric backside isolation layer 110 separates the conductive backside isolation layer 112 from the first semiconductor substrate 106. The backside DTI structure 108 is in the active pixel region 102 of the integrated chip and extends along a border between the active pixel region 102 and a dummy pixel region 114 of the integrated chip.

A first dielectric structure 116 is over the first semiconductor substrate 106 and extends along a backside 106b of the first semiconductor substrate 106. The first dielectric structure 116 comprises one or more dielectric layers. Color filters 118 are over the first dielectric structure 116 in the active pixel region 102. In some EE, the color filters 118 are also over the first dielectric structure 116 in the dummy pixel region 114. Micro lenses 119 are over the color filters 118 in the active pixel region 102.

A second dielectric structure 120 is under the first semiconductor substrate 106 and extends along a frontside 106a of the first semiconductor substrate 106. The second dielectric structure 120 comprises a plurality of dielectric layers. A gate electrode 122 (e.g., a transfer gate electrode, a reset gate electrode, a source follower gate electrode, a row select gate electrode, or the like) is directly under a photodetector 104 and within (e.g., between sidewalls of) the second dielectric structure 120. The interconnect structure 124 includes a plurality of contacts 126, a plurality of conductive lines 128, and a plurality of conductive vias 130 within the second dielectric structure 120.

In some embodiments, defects may exist along sidewalls of the first semiconductor substrate 106 where the first semiconductor substrate 106 borders the dielectric backside isolation layer 110 of the backside DTI structure 108. These defects may increase a dark current in the photodetectors 104. However, applying a bias to the backside DTI structure 108 can reduce the dark current and thus improve the performance of the image sensor. For example, applying a negative bias to the conductive backside isolation layer 112 can cause holes (e.g., positive charge carriers) to be attracted to the backside DTI structure 108. These holes can combine with stray electrons from the backside trench defects and prevent the stray electrons from reaching the photodetectors and generating dark current. Thus, in various embodiments of the present disclosure, the frontside DTI structure 132 couples the conductive backside isolation layer 112 to the interconnect structure 124 so that a bias can be provided to the backside DTI structure 108 through the frontside DTI structure 132 to improve the performance of the image sensor.

The frontside DTI structure 132 comprises a conductor (e.g., a conductive frontside isolation layer). The frontside DTI structure 132 is in the dummy pixel region 114 and directly under a portion 109 of the backside DTI structure 108 that is in the dummy pixel region 114. Portion 109 of the backside DTI structure 108 extends through the first semiconductor substrate 106 from the backside 106b to the frontside 106a. Portion 109 of the dielectric backside isolation layer 110 extends from the backside 106b to the frontside 106a (e.g., to a top of the second dielectric structure 120). Portion 109 of the conductive backside isolation layer 112 extends through the frontside 106a and into the second dielectric structure 120. The frontside DTI structure 132 extends through the second dielectric structure 120 from a conductive interconnect (e.g., a conductive line 128) of the interconnect structure 124 to portion 109 of the conductive backside isolation layer 112. Because the frontside DTI structure 132 is disposed outside of the active pixel region 102 (e.g., in the dummy pixel region 114), the frontside DTI structure 132 has reduced impact on the performance of the image sensor.

In some embodiments, a bias circuit 134 is coupled to the conductive backside isolation layer 112 of the backside DTI structure 108 through the interconnect structure 124 and the frontside DTI structure 132. The bias circuit 134 provides the bias (e.g., voltage) to the conductive backside isolation layer 112 of the backside DTI structure 108 through the interconnect structure 124 and the frontside DTI structure 132.

In some embodiments, the integrated chip further includes a second frontside DTI structure 202 and a third frontside DTI structure 204 spaced from frontside DTI structure 132. Frontside DTI structure 202 and frontside DTI structure 204 extend from the interconnect structure 124 to the backside DTI structure 108 in the dummy pixel region 114 and further couple the interconnect structure 124 to the conductive backside isolation layer 112. In some embodiments, the second frontside DTI structure 202 and the third frontside DTI structure 204 include the same conductive material as the frontside DTI structure 132. For example, a conductive frontside isolation layer (not labeled) forms frontside DTI structure 132, frontside DTI structure 202, and frontside DTI structure 204. Frontside DTI structures 132, 204, 204 are shown “in phantom” (e.g., by dashed lines) in FIG. 2 so that they can be seen in relation to the backside DTI structure 108 in top view 200. In some embodiments, the frontside DTI structures 132, 202, 204 may be referred to as a DTI contacts.

In some embodiments, the portion (not labeled) of the backside DTI structure 108 that is in the active pixel region 102 extends into the first semiconductor substrate 106 but not through the first semiconductor substrate 106. For example, in the active pixel region 102, the first semiconductor substrate 106 extends directly under the backside DTI structure 108.

In some embodiments, the first semiconductor substrate 106 comprises silicon or some other suitable semiconductor. In some embodiments, the dielectric backside isolation layer 110 comprises a hafnium oxide, zirconium dioxide, aluminum oxide, silicon oxide, or some other suitable material. In some embodiments, the conductive backside isolation layer 112 comprises tungsten, aluminum, titanium, copper, or some other suitable material. In some embodiments, the dielectric layers of the first dielectric structure 116 and/or the dielectric layers of the second dielectric structure 120 comprise silicon oxide, silicon nitride, silicon carbide, aluminum oxide, or some other suitable material. In some embodiments, the frontside DTI structure 132 comprises tungsten, aluminum, titanium, or some other suitable material. In some embodiments, the gate electrode 122 comprises polysilicon, tungsten, titanium, tantalum, or some other suitable material. In some embodiments, the contacts 126, the conductive lines 128, and the conductive vias 130 of the interconnect structure 124 comprise copper, aluminum, tungsten, titanium, ruthenium, or some other suitable material.

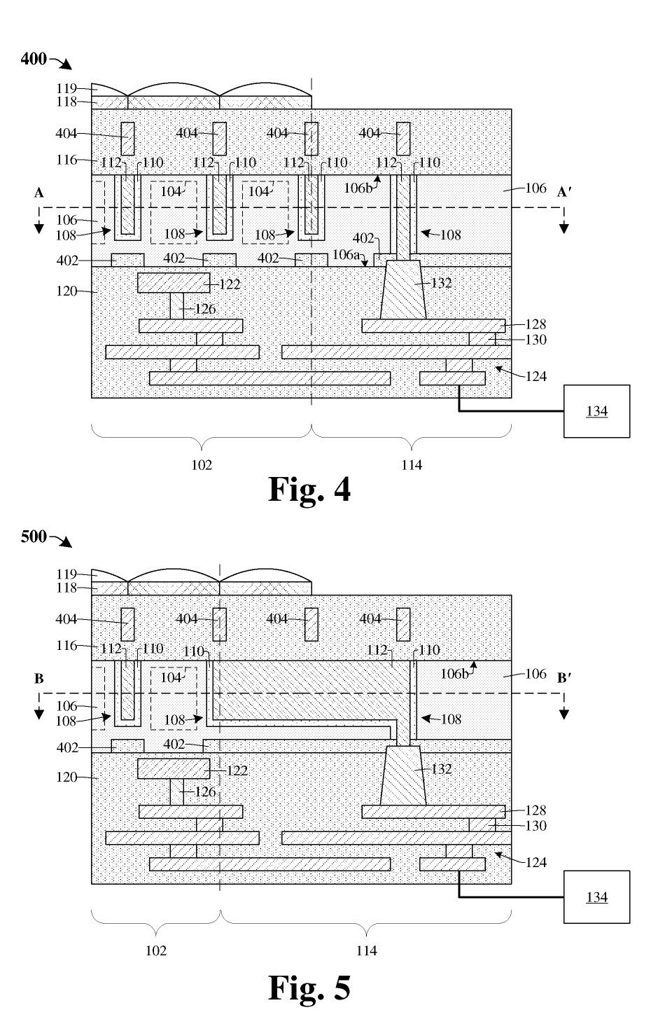

FIG. 3 illustrates a cross-sectional view 300 of some embodiments of the integrated chip of FIG. 1 in which the portion (not labeled) of the backside DTI structure 108 that is in the active pixel region 102 extends through the first semiconductor substrate 106 to the second dielectric structure 120. In some embodiments, section line A-A′ of FIG. 3 corresponds to section line A-A′ of FIG. 2.

In the active pixel region 102, the dielectric backside isolation layer 110 extends from the backside 106b to the frontside 106a and to the second dielectric structure 120. Further, in the active pixel region 102, the conductive backside isolation layer 112 extends from the backside 106b through the frontside 106a and into the second dielectric structure 120. In some embodiments, the conductive backside isolation layer 112 in the active pixel region 102 extends to the same depth below the backside 106b of the first semiconductor substrate 106 as the conductive backside isolation layer 112 in the dummy pixel region 114 (where the conductive backside isolation layer 112 lands on the frontside DTI structure 132).

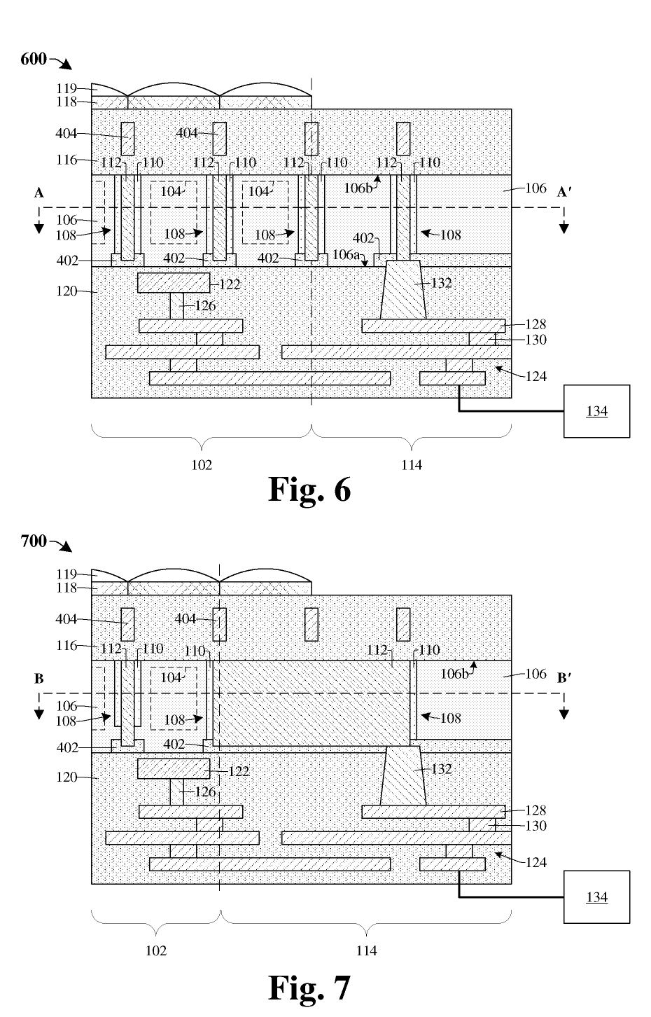

FIG. 4 illustrates cross-sectional view 400 and FIG. 5 illustrates cross-sectional view 500 of some embodiments of the integrated chip of FIG. 1 further including a dielectric frontside shallow trench isolation (STI) structure 402 under the backside DTI structure 108 and a conductive grid 404 over the backside DTI structure 108. In some embodiments, section line A-A′ of FIG. 4 corresponds to section line A-A′ of FIG. 2. In some embodiments, section line B-B′ of FIG. 5 corresponds to section line B-B′ of FIG. 2.

FIG. 6 illustrates cross-sectional view 600 and FIG. 7 illustrates cross-sectional view 700 of some embodiments of the integrated chip of FIG. 3 further including the frontside STI structure 402 under the backside DTI structure 108 and the conductive grid 404 over the backside DTI structure 108. In some embodiments, section line A-A′ of FIG. 6 corresponds to section line A-A′ of FIG. 2. In some embodiments, section line B-B′ of FIG. 7 corresponds to section line B-B′ of FIG. 2.

Referring to FIGS. 4-7, the frontside STI structure 402 is in a frontside shallow trench (not labeled) in the first semiconductor substrate 106 that extends into the first semiconductor substrate 106 from the frontside 106a toward the backside 106b. The frontside STI structure 402 is directly under the backside DTI structure 108 and extends between the photodetectors 104 in a grid-like layout along the frontside 106a of the first semiconductor substrate 106. The frontside STI structure 402 includes one or more dielectric layers (e.g., dielectric frontside isolation layer(s)). In some embodiments, the frontside STI structure 402 is part of dielectric structure 120. In some embodiments, the frontside STI structure 402 comprises silicon dioxide, silicon nitride, or some other suitable material.

The frontside DTI structure 132 extends into the frontside STI structure 402 from below the frontside STI structure 402 to below a top of the frontside STI structure 402. A top surface (not labeled) of the frontside DTI structure 132 is above the frontside 106a of the first semiconductor substrate 106 and spaced directly under a lower surface (not labeled) of the first semiconductor substrate 106 with the frontside STI structure 402 therebetween. The backside DTI structure 108 (e.g., portion 109 of the backside DTI structure 108) extends into the frontside STI structure 402 directly over the frontside DTI structure 132.

The conductive grid 404 is spaced over the first semiconductor substrate 106 and within the first dielectric structure 116. The conductive grid 404 is in both the active pixel region 102 and the dummy pixel region 114 of the integrated chip. The conductive grid 404 is directly over the backside DTI structure 108 and has a in a grid-like layout. In some embodiments, the conductive grid 404 comprises tungsten, titanium nitride, or some other suitable material.

In some embodiments (as illustrated in FIG. 4 and FIG. 5), in the active pixel region 102, the backside DTI structure 108 is spaced over the frontside STI structure 402 with the first semiconductor substrate 106 therebetween. In some other embodiments (e.g., as illustrated in FIG. 6 and FIG. 7), in the active pixel region, the backside DTI structure 108 extends through the first semiconductor substrate 106 into the frontside STI structure 402.

FIGS. 8-10 illustrate cross-sectional views 800-1000 of various embodiments of the backside DTI structure 108 and the frontside DTI structure 132 of any of FIGS. 1-7.

In some embodiments (e.g., as illustrated in FIG. 8), the frontside DTI structure 132 and the backside DTI structure 108 have a lateral offset. For example, the backside DTI structure 108 extends along a top surface 132a of the frontside DTI structure 132 and below the top surface 132a along an outer sidewall 132b of the frontside DTI structure 132.

In some embodiments (e.g., as illustrated in FIG. 9), the backside DTI structure 108 extends into the frontside DTI structure 132. For example, the backside DTI structure 108 is between a pair of inner sidewalls 132c of the frontside DTI structure 132 and on an upper surface 132d of the frontside DTI structure 132 that is below the top surface 132a of the frontside DTI structure 132.

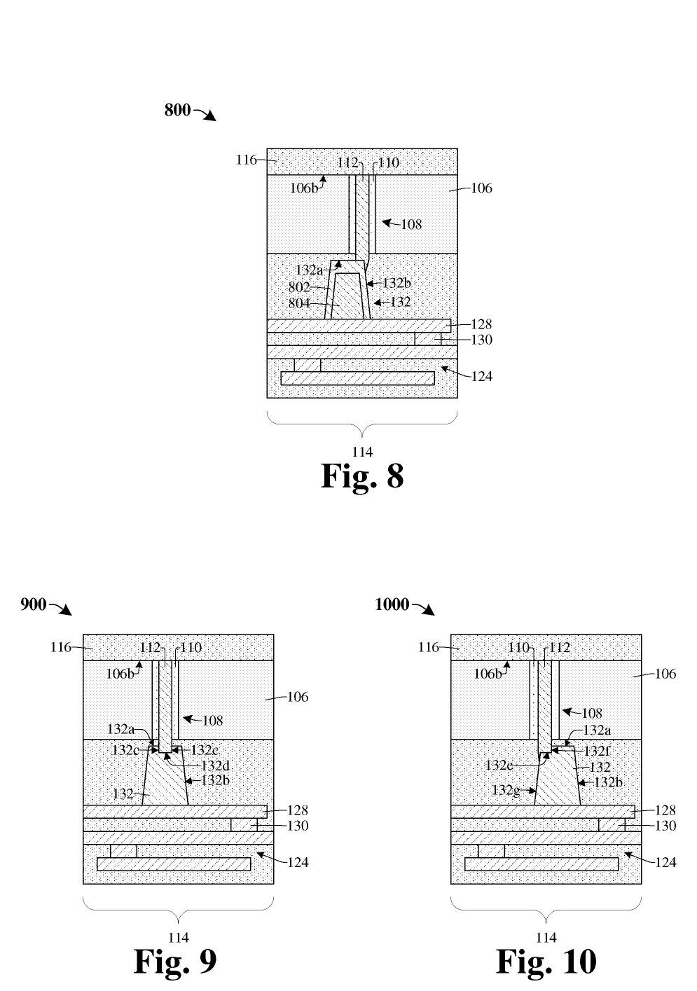

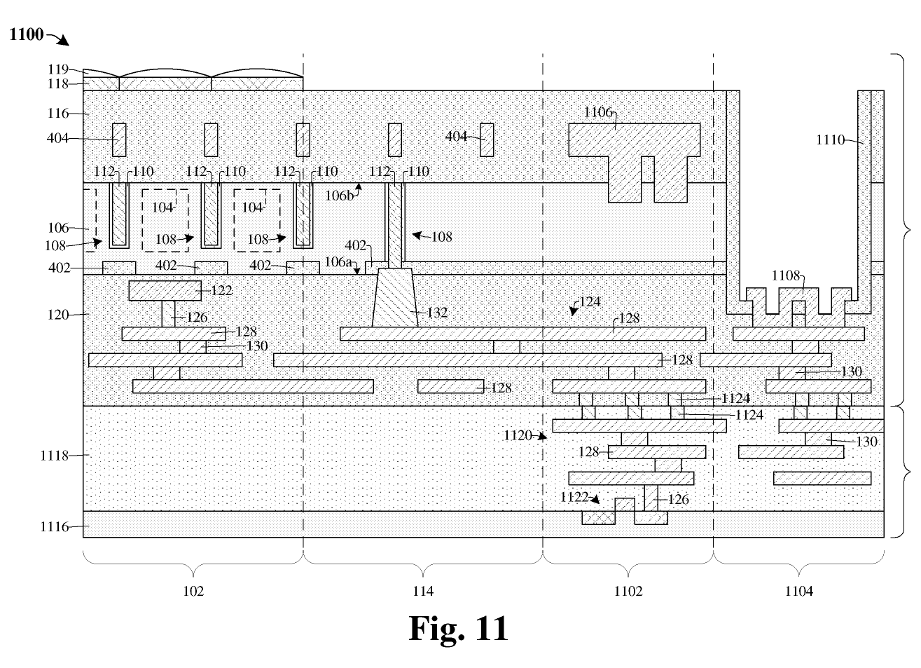

In some embodiments (e.g., as illustrated in FIG. 10), the backside DTI structure 108 extends into the frontside DTI structure 132, and the frontside DTI structure 132 and the backside DTI structure 108 have a lateral offset. For example, the backside DTI structure 108 is on an upper surface 132e of the frontside DTI structure 132 that is below a top surface 132a of the frontside DTI structure 132, and the backside DTI structure 108 extends along an inner sidewall 132f and an outer sidewall 132g of the frontside DTI structure 132.

In some embodiments (e.g., as illustrated in FIG. 8), the frontside DTI structure 132 includes a first conductive frontside isolation layer 802 and a second conductive frontside isolation layer 804. The first conductive frontside isolation layer 802 lines the frontside deep trench (not labeled) and contacts the conductive backside isolation layer 112. The second conductive frontside isolation layer 804 is over the first conductive frontside isolation layer 802 and fills the frontside deep trench. In some such embodiments, the first conductive frontside isolation layer 802 comprises a first conductor and the second conductive frontside isolation layer 804 comprises a second conductor different than the first conductor.

FIG. 11 illustrates a cross-sectional view 1100 of some embodiments of the integrated chip of FIG. 4 further including a black level correction region 1102 beside the dummy pixel region 114, and a pad region 1104 beside the black level correction region 1102.

A backside grounding electrode 1106 is in the black level correction region 1102. The backside grounding electrode 1106 is laterally spaced from the conductive grid 404 and coupled to the conductive grid 404. The backside grounding electrode 1106 is within the first dielectric structure 116 and extends into the first semiconductor substrate 106. The backside grounding electrode 1106 contacts the first semiconductor substrate 106 and couples the conductive grid 404 to the first semiconductor substrate 106. In some embodiments, the backside grounding electrode 1106 comprises tungsten, titanium nitride, or some other suitable material.

A pad trench (not labeled) and a conductive pad 1108 are in the pad region 1104 of the integrated chip. The pad trench is delimited by sidewalls of the first dielectric structure 116, sidewalls of the first semiconductor substrate 106, and sidewalls of the second dielectric structure 120. The conductive pad 1108 is at the bottom of the pad trench. In some embodiments, the conductive pad 1108 comprises tungsten, aluminum, titanium, titanium nitride, copper, or some other suitable material. A dielectric layer 1110 lines the pad trench. The conductive pad 1108 is on and extends through the dielectric layer 1110 to interconnect structure 124 (e.g., a conductive line 128 of interconnect structure 124). In some embodiments, dielectric layer 1110 comprises silicon oxide, silicon nitride, some high-k dielectric, or some other suitable material.

The first semiconductor substrate 106, the photodetectors 104, the first dielectric structure 116, the conductive grid 404, the color filters 118, the micro lenses 119, the backside grounding electrode 1106, the second dielectric structure 120, interconnect structure 124, and the conductive pad 1108 are on a first chip 1112. A second chip 1114 is bonded under the first chip 1112. The second chip includes a second semiconductor substrate 1116, a dielectric structure 1118 (including a plurality of dielectric layers) over the second semiconductor substrate 1116, and an interconnect structure 1120 (including contacts 126, conductive lines 128, and conductive vias 130, and the like) is within dielectric structure 1118. Interconnect structure 124 and interconnect structure 1120 include bonding pads 1124. The first chip 1112 and the second chip 1114 are bonded along the bonding pads 1124 and along the dielectric structures 120, 1118.

Transistors 1122 are disposed along the second semiconductor substrate 1116. In some embodiments, the transistors 1122 are part of the bias circuit 134. The transistors 1122 are coupled to interconnect structure 124 through interconnect structure 1120. For example, a transistor 1122 of the bias circuit 134 is coupled to the frontside DTI structure 132 through interconnect structure 1120 and interconnect structure 124. In some embodiments, the transistors 1122 comprise metal-oxide-semiconductor field-effect transistors (MOSFETs), bipolar junction transistors (BJTs), junction field effect transistors (JFETs), fin field effect transistors (FinFETs), gate all-around field effect transistors (GAAFETs), or some other suitable devices.

In some integrated chips, the backside DTI structure 108 is coupled to the conductive pad 1108 through the conductive grid 404 and the backside grounding electrode 1106, and a bias is provided to the backside DTI structure 108 through the conductive pad 1108, the backside grounding electrode 1106, and the conductive grid 404. However, this routing may have increased complexity which may limit the flexibility of the design of the integrated chip and may increase a cost of the integrated chip. By coupling the backside DTI structure 108 to interconnect structure 124 through the frontside DTI structure 132, as illustrated in various embodiments of the present disclosure, the routing can be simplified. Further, the by coupling the backside DTI structure 108 to interconnect structure 124 through the frontside DTI structure 132, the backside DTI structure 108 and the conductive grid 404 can have separate biases which can increase the flexibility of the design of the integrated chip. As a result, a performance of the integrated chip can be improved and a cost of the integrated chip can be reduced.

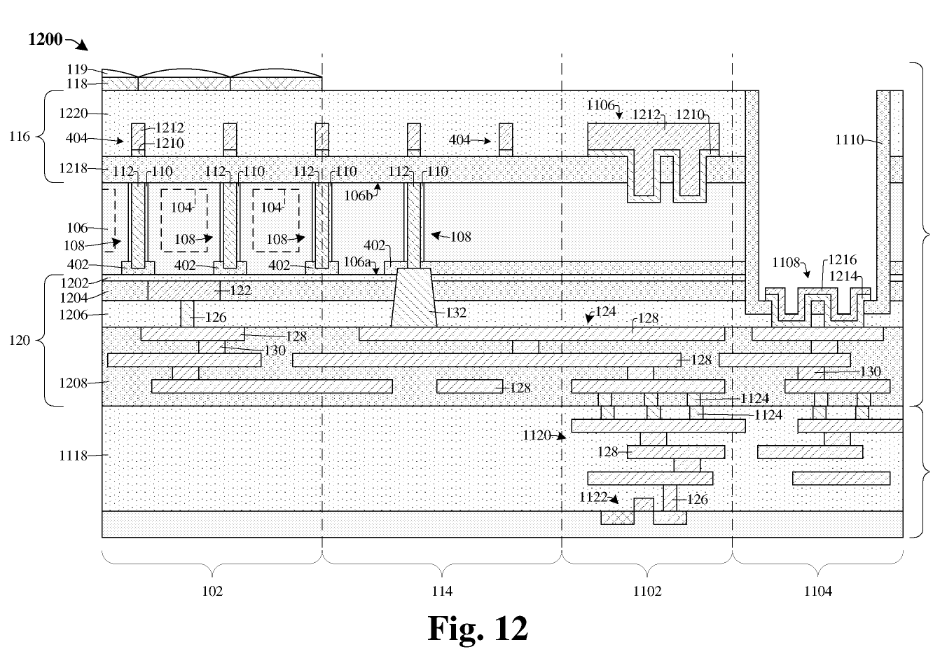

FIG. 12 illustrates a cross-sectional view 1200 of some embodiments of the integrated chip of FIG. 11.

In some embodiments, the second dielectric structure 120 includes a gate dielectric layer 1202, a dielectric layer 1204, a dielectric layer 1206, and dielectric layer(s) 1208. The gate dielectric layer 1202 is under the first semiconductor substrate 106 and extending along the frontside 106a of the first semiconductor substrate 106 between the gate electrode 122 and the frontside 106a. Dielectric layer 1204 is under the gate dielectric layer 1202. The gate electrode 122 is between sidewalls of dielectric layer 1204. Dielectric layer 1206 is under dielectric layer 1204. A contact 126 extends through dielectric layer 1206 to the gate electrode 122. The frontside DTI structure 132 extends through dielectric layer 1206, dielectric layer 1204, and the gate dielectric layer 1202 into the frontside STI structure 402. Dielectric layer(s) 1208 are under dielectric layer 1206 and conductive interconnects (e.g., conductive lines 128, conductive vias 130, bonding pads 1124, and the like) are within dielectric layer(s) 1208. In some embodiments, dielectric layers 1202, 1204, 1206, 1208 comprise silicon oxide, silicon nitride, silicon carbide, aluminum oxide, some high-k dielectric, or some other suitable material.

In some embodiments, dielectric structure 116 includes a dielectric layer 1218 over the backside 106b of the first semiconductor substrate 106 and a dielectric layer 1220 over dielectric layer 1218. In some embodiments, the conductive grid 404 is on dielectric layer 1218 and between sidewalls of dielectric layer 1220. In some embodiments, dielectric layer 1218 and dielectric layer 1220 comprise silicon oxide, silicon nitride, some high-k dielectric, or some other suitable material.

In some embodiments, the conductive grid 404 includes a first conductive layer 1210 and a second conductive layer 1212 over the first conductive layer 1210. Further, the backside grounding electrode 1106 includes the first conductive layer 1210 and the second conductive layer 1212 over the first conductive layer 1210. In some embodiments, conductive layer 1210 comprises titanium nitride or some other suitable material and conductive layer 1212 comprises tungsten or some other suitable material.

In some embodiments, the conductive pad 1108 includes a first conductive pad layer 1214 and a second conductive pad layer 1216 over the first conductive pad layer 1214. In some embodiments, conductive pad layer 1214 and/or conductive pad layer 1216 comprise tungsten, aluminum, titanium, titanium nitride, copper, or some other suitable material.

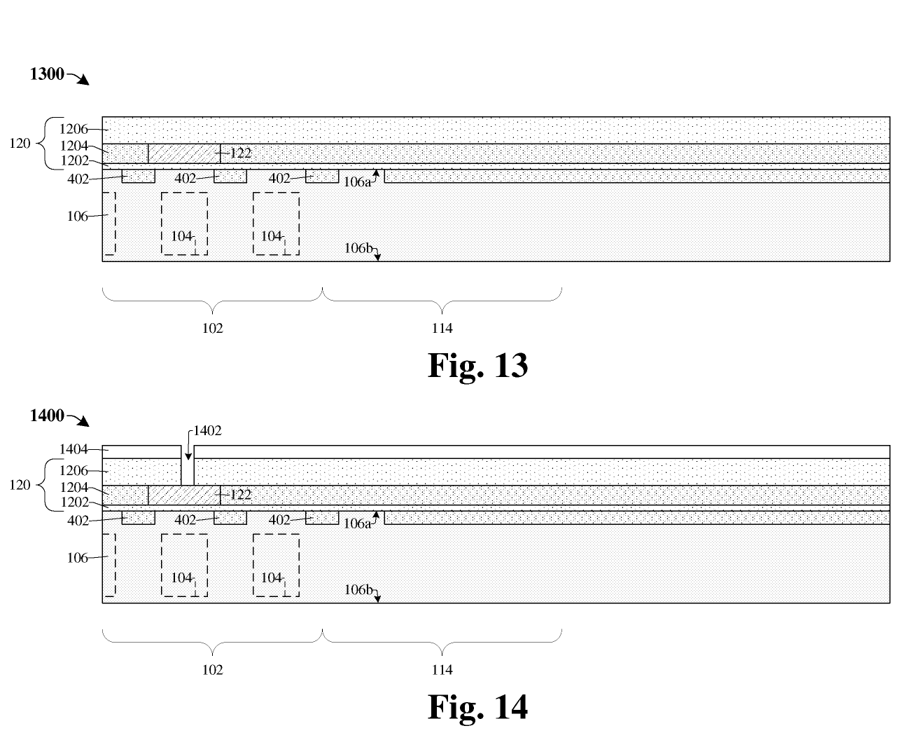

FIGS. 13-36 illustrate cross-sectional views 1300-3600 of some embodiments of a method for forming an integrated chip including a frontside DTI structure 132 which couples an interconnect structure 124 to a backside DTI structure 108. Although FIGS. 13-36 are described in relation to a method, it will be appreciated that the structures disclosed in FIGS. 13-36 are not limited to such a method, but instead may stand alone as structures independent of the method.

As shown in cross-sectional view 1300 of FIG. 13, photodetectors 104 (e.g., photodiodes) are formed along a first semiconductor substrate 106 in an active pixel region 102 of the integrated chip. Further, the first semiconductor substrate 106 is etched from the frontside 106a toward the backside to form a frontside shallow trench (not labeled) in the first semiconductor substrate 106, and a dielectric is deposited in the frontside shallow trench to form a frontside STI structure 402. Further, a dielectric structure 120 (e.g., including a gate dielectric layer 1202, a dielectric layer 1204, and a dielectric layer 1206) and a gate electrode 122 are formed over the frontside 106a of the first semiconductor substrate 106. In some embodiments, the frontside STI structure 402 is considered part of dielectric structure 120.

As shown in cross-sectional view 1400 of FIG. 14, dielectric structure 120 (e.g., dielectric layer 1206) is etched to form a contact opening 1402 in the dielectric structure 120 which uncovers a portion of the gate electrode 122. In some embodiments, a masking layer 1404 is formed over dielectric structure 120 and the etching is performed according to the masking layer 1404. In some embodiments, the etching comprises a dry etching process (e.g., a plasma etching process, a reactive ion etching process, an ion beam etching process, or the like) or some other suitable process.

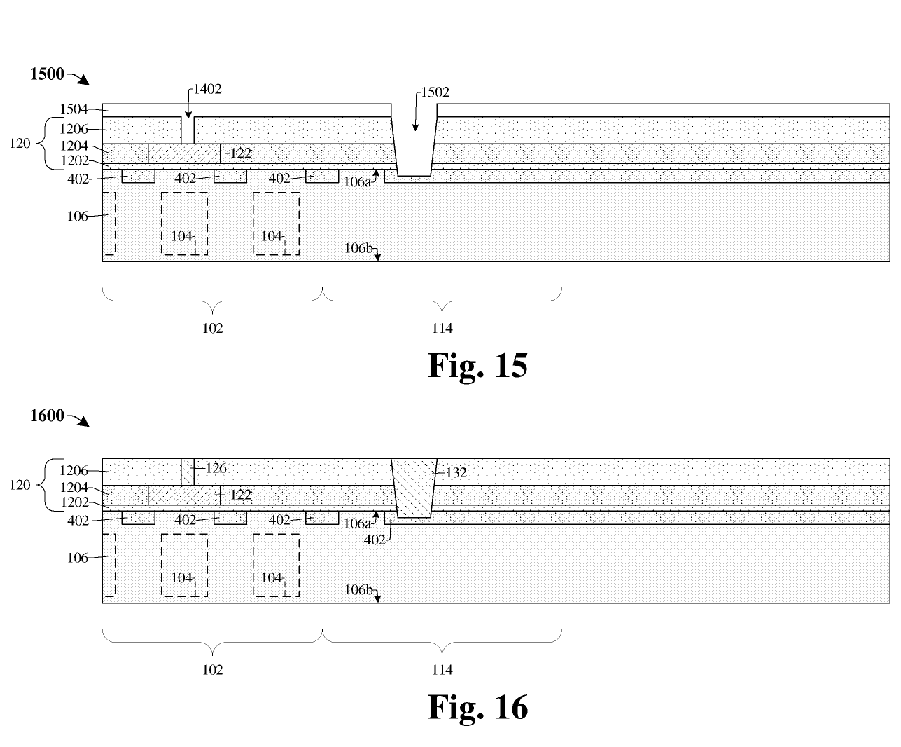

As shown in cross-sectional view 1500 of FIG. 15, dielectric structure 120 (e.g., dielectric layer 1206, dielectric layer 1204, and gate dielectric layer 1202) and the frontside STI structure 402 are etched to form a frontside deep trench 1502 in the dielectric structure 120 and the frontside STI structure 402 in a dummy pixel region 114 of the integrated chip. In some embodiments, a masking layer 1504 is formed over dielectric structure 120 and the etching is performed according to the masking layer 1504. In some embodiments, the etching comprises a dry etching process or some other suitable process. In some embodiments, additional frontside deep trenches (not shown) are formed in the dielectric structure 120 and the frontside STI structure 402 and laterally spaced from frontside deep trench 1502.

As shown in cross-sectional view 1600 of FIG. 16, a contact 126 is formed in the contact opening 1402 and a frontside DTI structure 132 is formed in the frontside deep trench 1502. In some embodiments, the contact 126 and the frontside DTI structure 132 are formed by depositing a conductive layer (not labeled) in the contact opening 1402 and the frontside deep trench 1502 and performing a planarization process on the conductive layer to remove the conductive layer from over dielectric structure 120 and to further delimit the contact 126 and the frontside DTI structure 132. In some embodiments, the conductive layer (not labeled) comprises tungsten, aluminum, titanium, or some other suitable material and is deposited by a chemical vapor deposition (CVD) process, a physical vapor deposition (PVD) process, an atomic layer deposition (ALD) process, or some other suitable process. In some embodiments, the planarization process comprises chemical mechanical planarization (CMP) process, a blanket etch back process, or some other suitable process.

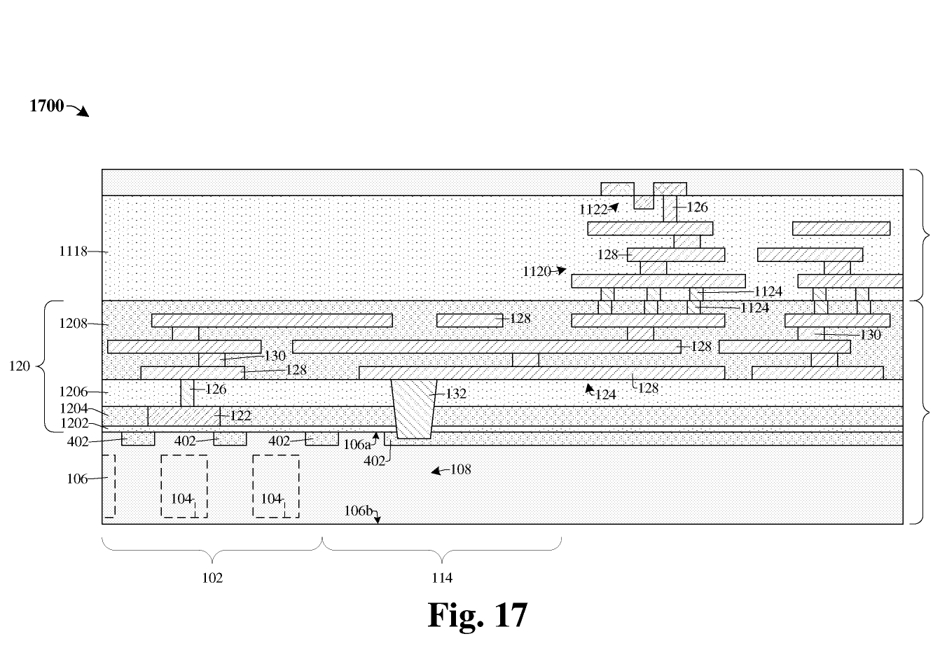

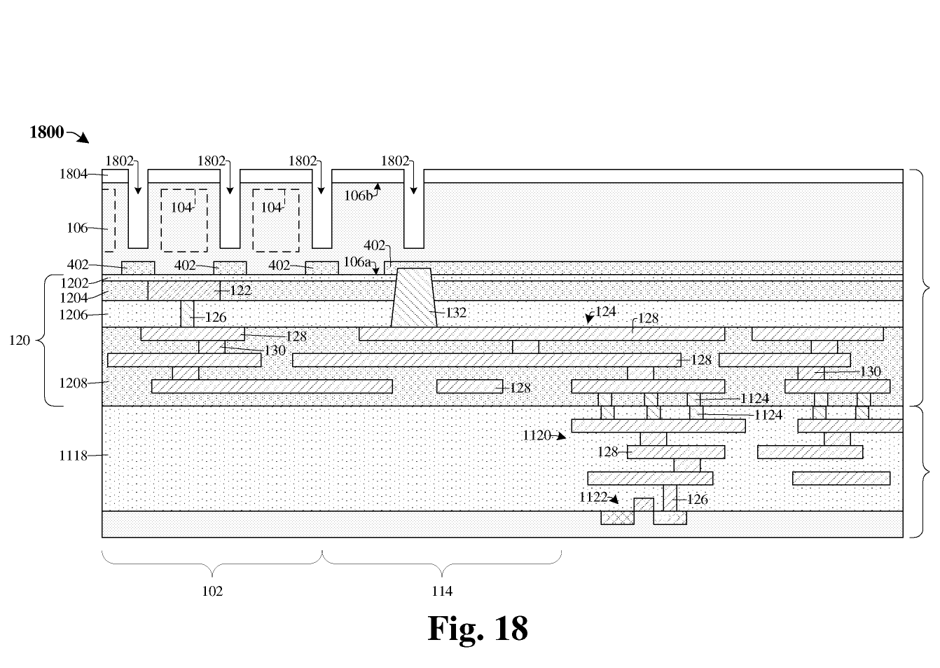

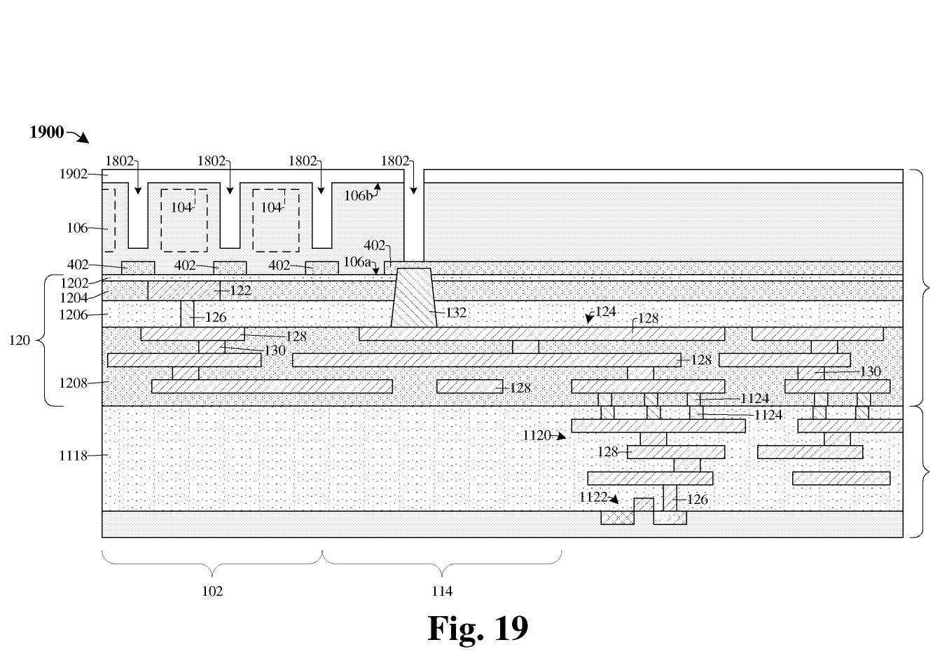

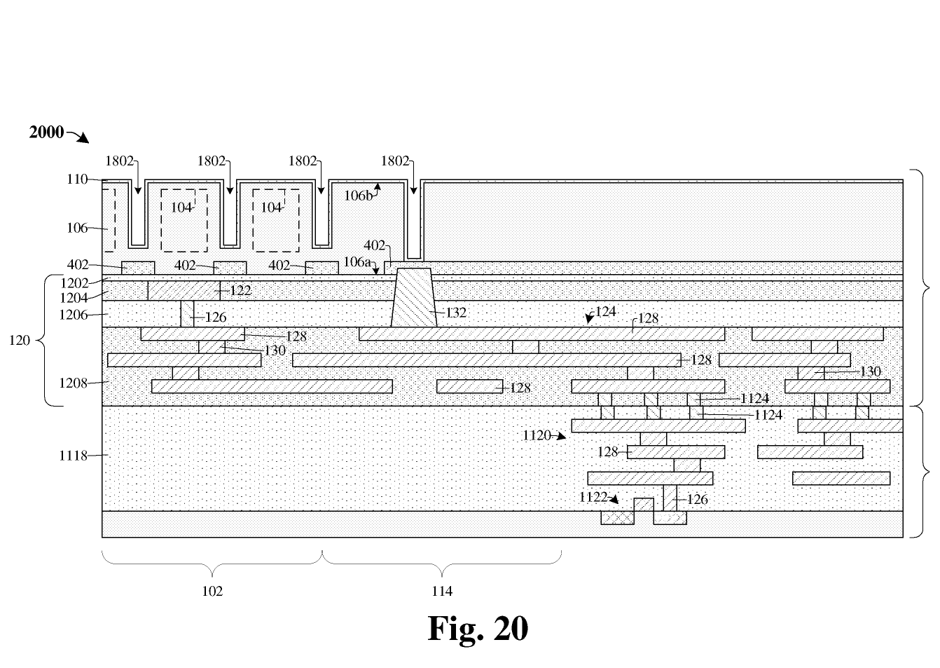

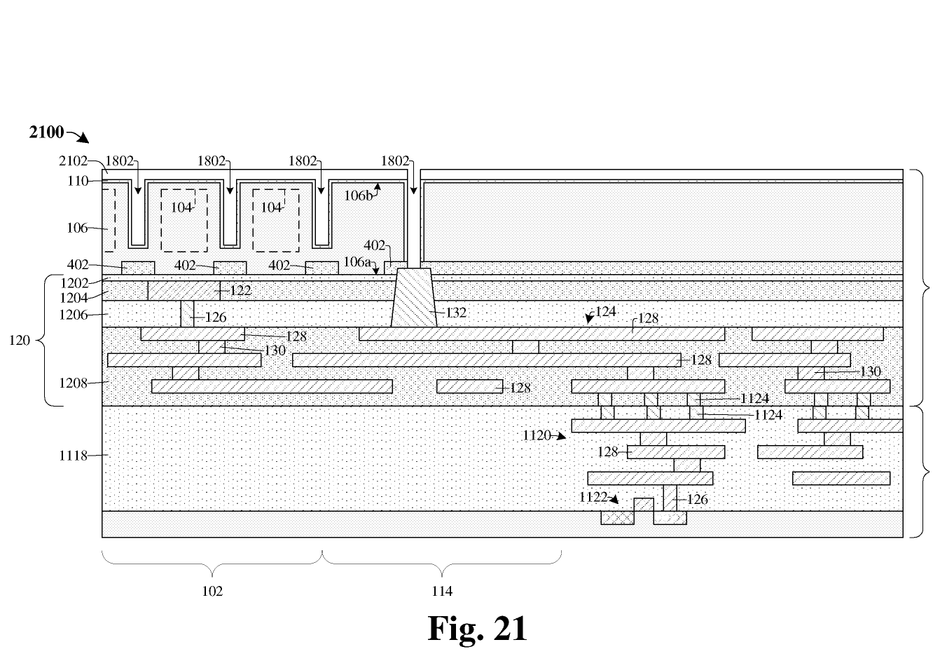

As shown in cross-sectional view 1700 of FIG. 17, dielectric layer(s) 1208 and conductive interconnects (e.g., conductive lines 128, conductive vias 130, bonding pads 1124, and the like) are formed over dielectric layer 1206. In addition, a second chip 1114 and the first chip 1112 are bonded together along bonding pads 1124 and dielectric structures 120, 1118. In some embodiments, the bonding comprises a thermal bonding process, a fusion bonding process, or some other suitable process.

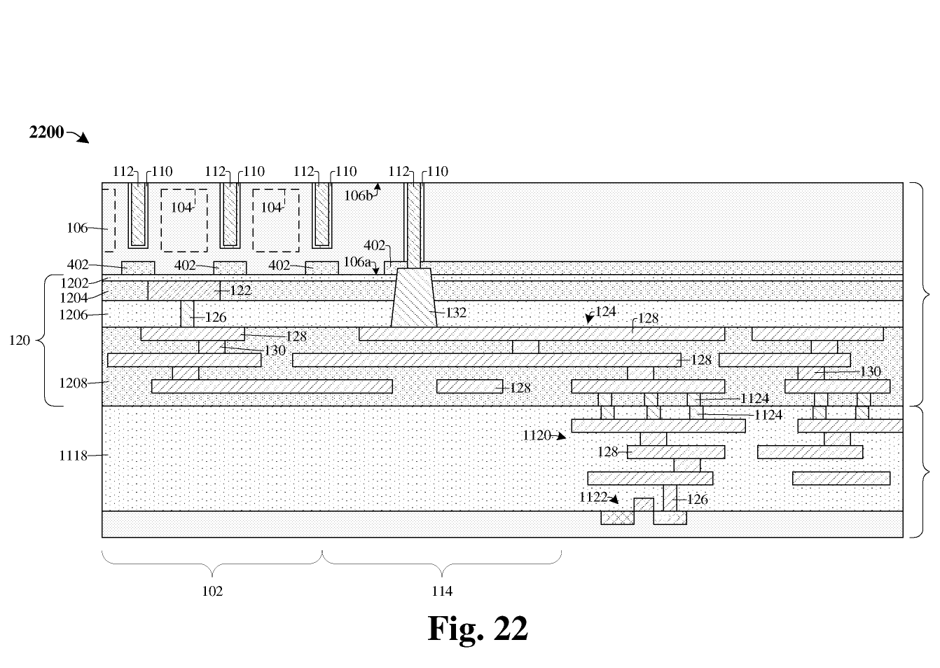

FIGS. 18-22 illustrate cross-sectional views 1800-2200 of some embodiments of a method for forming a backside DTI structure 108 in the first semiconductor substrate 106 and coupled to the frontside DTI structure 132.

As shown in cross-sectional view 1800 of FIG. 18, the first semiconductor substrate 106 is etched in the active pixel region 102 and the dummy pixel region 114 with a first etching process from the backside 106b toward the frontside 106a to form a backside trench 1802 in the first semiconductor substrate 106. The first etching process extends the backside trench 1802 to a depth below the backside 106b that is spaced over the frontside 106a and the frontside STI structure 402 (e.g., into the first semiconductor substrate 106 but not through the first semiconductor substrate 106) in both the active pixel region 102 and the dummy pixel region 114. In some embodiments, a masking layer 1804 is formed over the backside 106b and the etching is performed according to the masking layer 1804. In some embodiments, the etching comprises a dry etching process or some other suitable process.

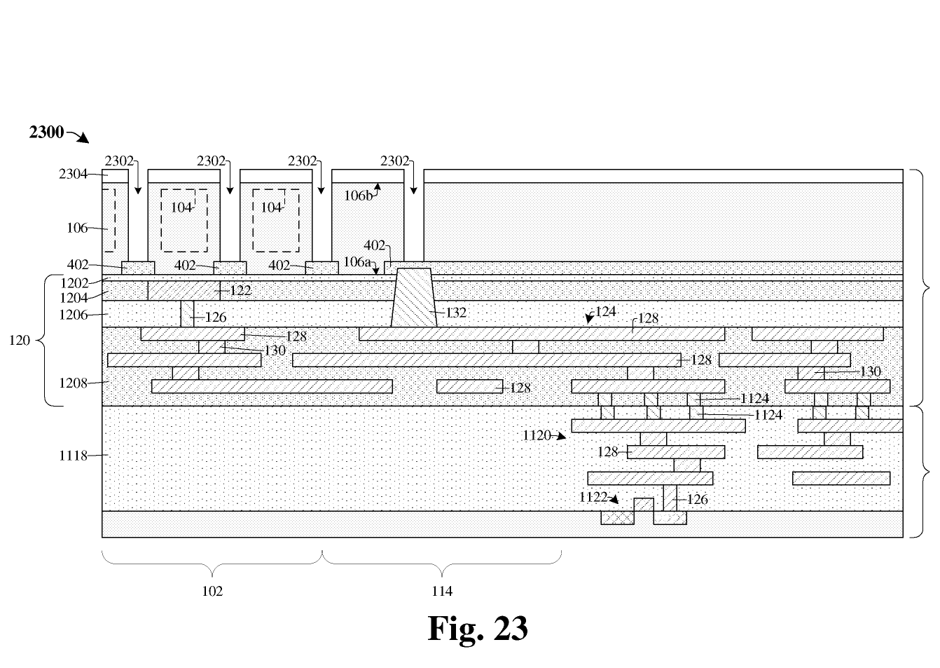

As shown in cross-sectional view 1900 of FIG. 19, the first semiconductor substrate 106 is etched in the dummy pixel region 114 with a second etching process from the backside 106b toward the frontside 106a to extend the backside trench 1802 through the first semiconductor substrate 106 to the frontside DTI structure 132 in the dummy pixel region 114. In some embodiments, a masking layer 1902 is formed over the backside 106b and in a portion of the backside trench 1802 that is in the active pixel region 102, and the etching is performed according to the masking layer 1902. In some embodiments, the etching comprises a dry etching process or some other suitable process.

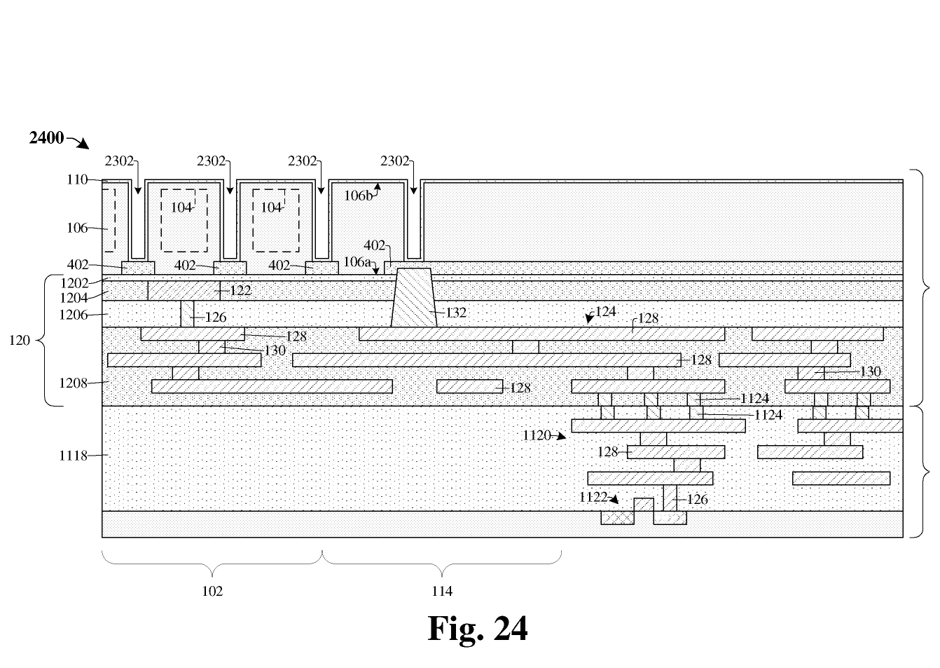

As shown in cross-sectional view 2000 of FIG. 20, a dielectric backside isolation layer 110 is deposited along the backside 106b and lining the backside trench 1802 (e.g., on sidewalls and an upper surface of the first semiconductor substrate 106 that delimit the backside trench 1802). In some embodiments, the dielectric backside isolation layer 110 comprises a hafnium oxide, zirconium dioxide, aluminum oxide, silicon oxide, or some other suitable material and is deposited by a CVD process, a PVD process, an ALD process, or some other suitable process.

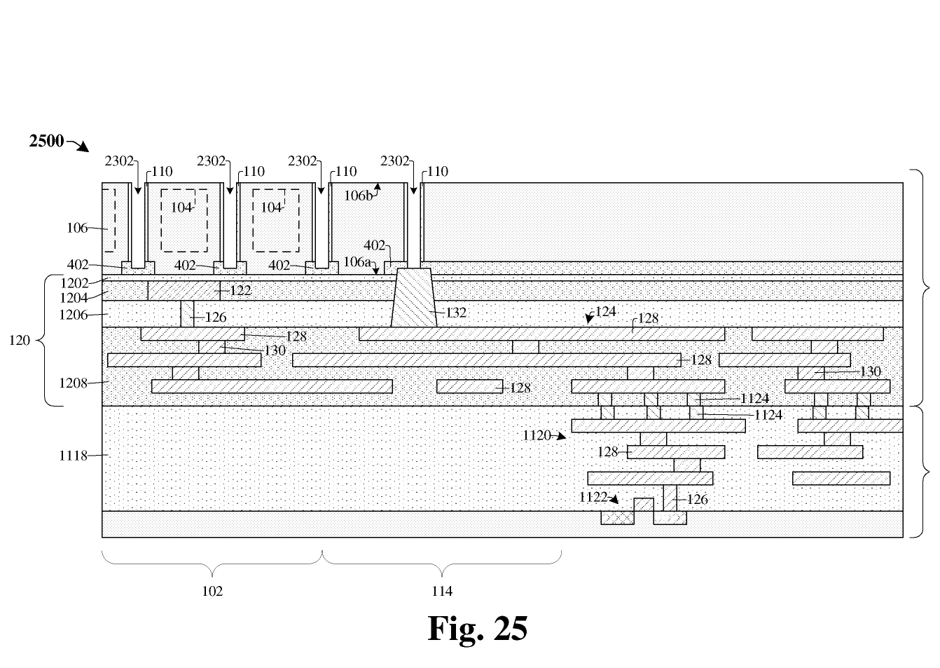

As shown in cross-sectional view 2100 of FIG. 21, the dielectric backside isolation layer 110 and the frontside STI structure 402 are etched in the dummy pixel region 114 with a third etching process to extend the backside trench 1802 through the dielectric backside isolation layer 110 and through the frontside STI structure 402 to the frontside DTI structure 132 to uncover the frontside DTI structure 132. In some embodiments, a masking layer 2102 is formed over the backside 106b and in a portion of the backside trench 1802 that is in the active pixel region 102, and the etching is performed according to the masking layer 2102. In some embodiments, the etching comprises a dry etching process or some other suitable process.

As shown in cross-sectional view 2200 of FIG. 22, a conductive backside isolation layer 112 is deposited in the backside trench 1802 on the dielectric backside isolation layer 110 and on the frontside DTI structure 132. The conductive backside isolation layer 112 fills the backside trench 1802. Further, a planarization process is performed on the conductive backside isolation layer 112 and the dielectric backside isolation layer 110 to remove the conductive backside isolation layer 112 and the dielectric backside isolation layer 110 from over backside 106b of the first semiconductor substrate 106. Together, the dielectric backside isolation layer 110 and the conductive backside isolation layer 112 form the backside DTI structure 108. In some embodiments, the conductive backside isolation layer 112 comprises tungsten, aluminum, titanium, or some other suitable material and is deposited by a CVD process, a PVD process, an ALD process, or some other suitable process. In some embodiments, the planarization process comprises CMP process, a blanket etch back process, or some other suitable process.

FIGS. 23-26 illustrate cross-sectional views 2300-2600 of some other embodiments of a method for forming the backside DTI structure 108 in the first semiconductor substrate 106 and coupled to the frontside DTI structure 132.

As shown in cross-sectional view 2300 of FIG. 23, the first semiconductor substrate 106 is etched in the active pixel region 102 and the dummy pixel region 114 with a first etching process from the backside 106b toward the frontside 106a to form a backside trench 2302 in the first semiconductor substrate 106. The first etching process extends the backside trench 2302 through the first semiconductor substrate 106 to the frontside STI structure 402 in both the active pixel region 102 and the dummy pixel region 114. In some embodiments, a masking layer 2304 is formed over the backside 106b and the etching is performed according to the masking layer 2304. In some embodiments, the etching comprises a dry etching process or some other suitable process.

As shown in cross-sectional view 2400 of FIG. 24, the dielectric backside isolation layer 110 is deposited along the backside 106b and lining the backside trench 2302 (e.g., on sidewalls of the first semiconductor substrate 106 that delimit the backside trench 2302 and on upper surfaces of the frontside STI structure 402 that delimit the backside trench 2302).

As shown in cross-sectional view 2500 of FIG. 25, the dielectric backside isolation layer 110 and the frontside STI structure 402 are etched in the active pixel region 102 and the dummy pixel region 114 with a second etching process to extend the backside trench 2302 through the dielectric backside isolation layer 110 and into the frontside STI structure 402 to the frontside DTI structure 132 in both the active pixel region 102 and the dummy pixel region 114. The etching uncovers the frontside DTI structure 132 in the dummy pixel region 114. In some embodiments, the etching removes the dielectric backside isolation layer 110 from over the backside 106b of the first semiconductor substrate 106. In some embodiments, the etching comprises a dry etching process or some other suitable process. In some embodiments, the etching is a blanket etching process performed without a masking layer.

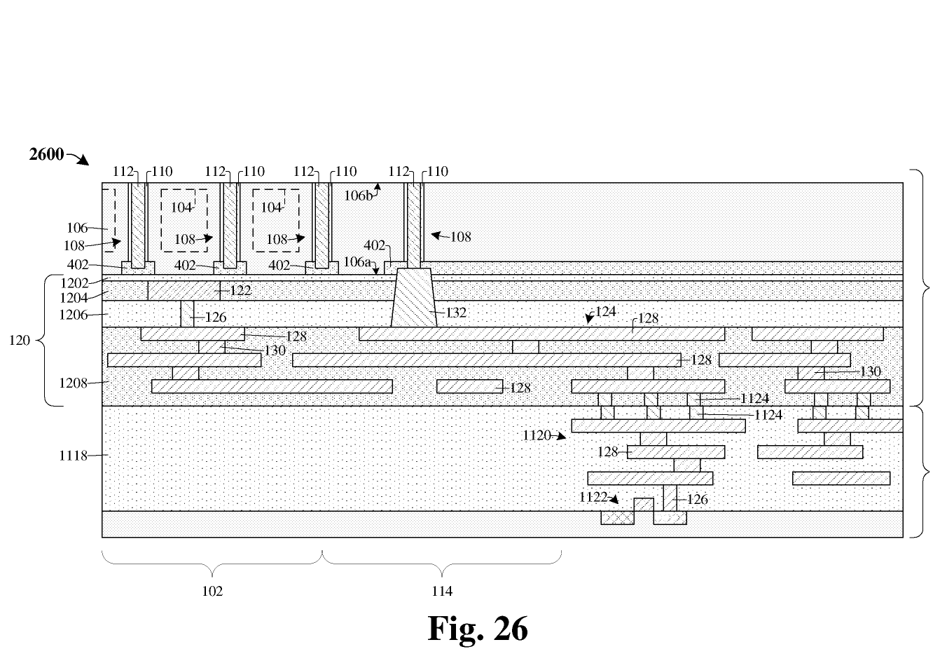

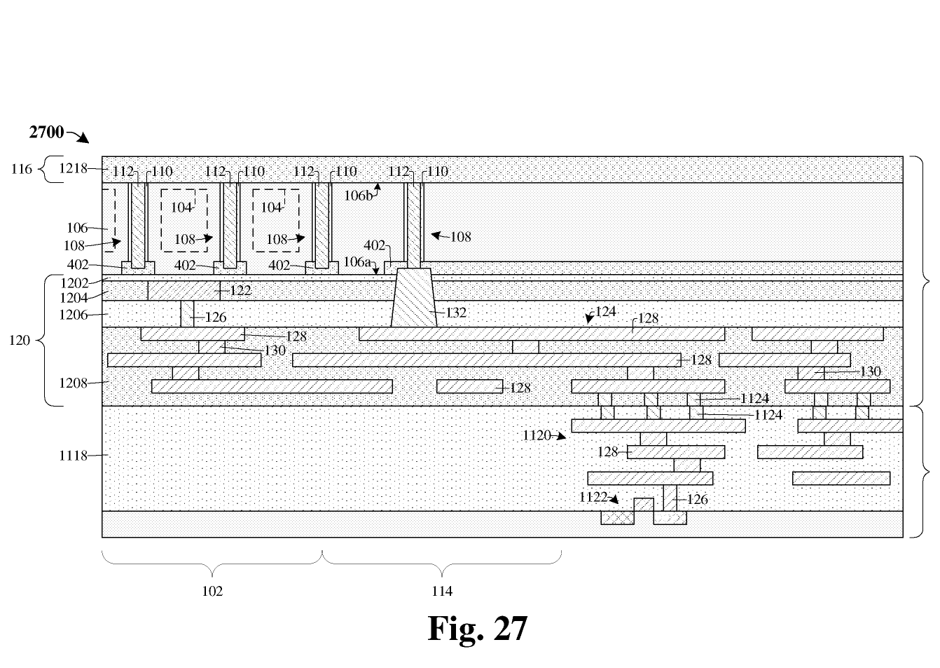

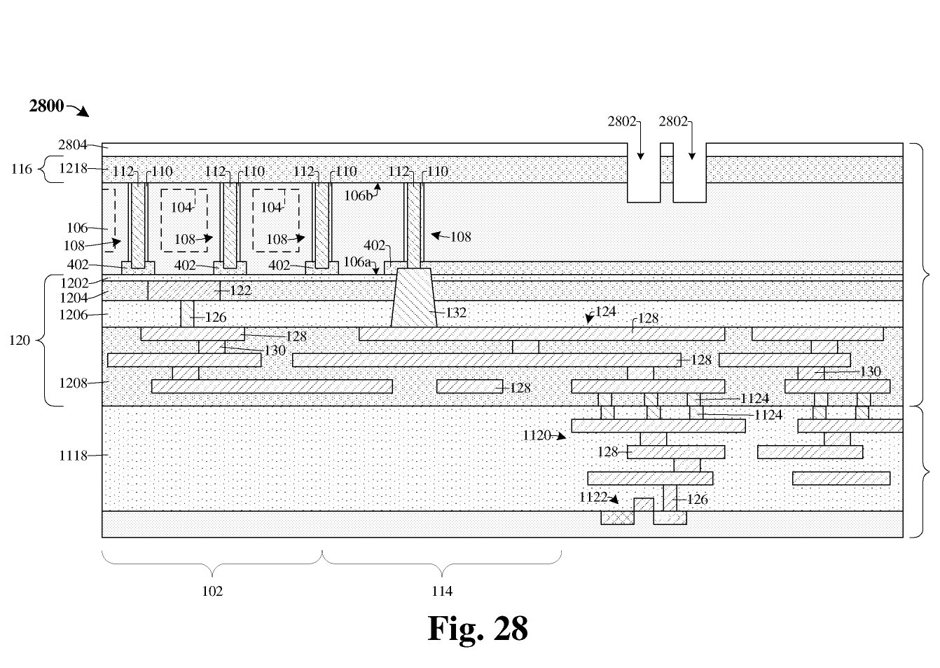

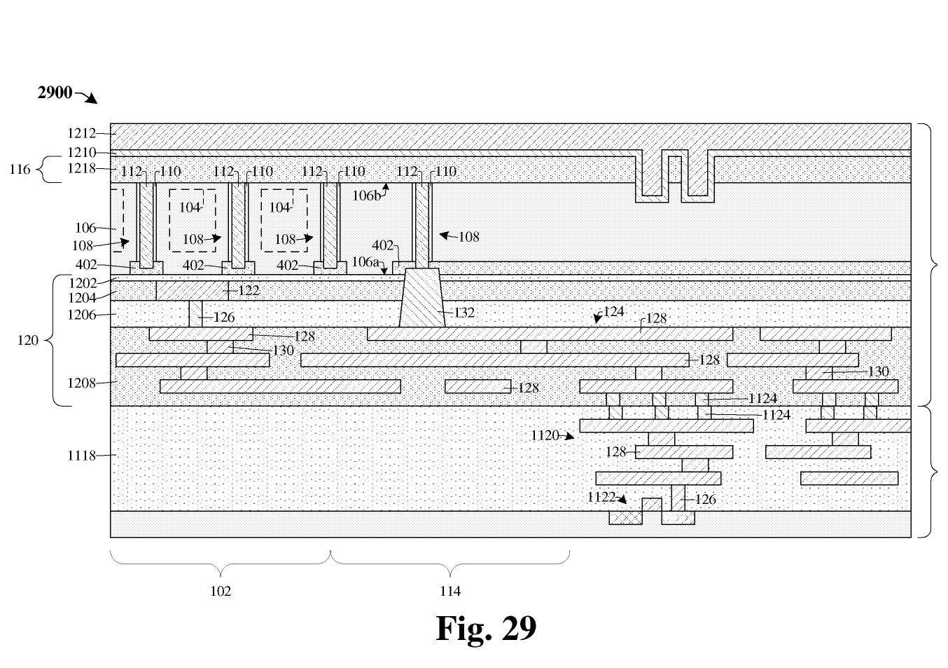

As shown in cross-sectional view 2600 of FIG. 26, the conductive backside isolation layer 112 is deposited in the backside trench 2302, on the dielectric backside isolation layer 110, on the frontside STI structure 402, and on the frontside DTI structure 132. The conductive backside isolation layer 112 fills the backside trench 2302. Further, a planarization process is performed on the conductive backside isolation layer 112 to remove the conductive backside isolation layer 112 from over backside 106b of the first semiconductor substrate 106. Together, the dielectric backside isolation layer 110 and the conductive backside isolation layer 112 form the backside DTI structure 108.

FIGS. 27-36 illustrate cross-sectional views 2300-3600 of some embodiments of a method for forming a remainder of the integrated chip. Although the backside DTI structure 108 is illustrated as extending through the first semiconductor substrate 106 into the frontside STI structure 402 in the active pixel region 102 in FIGS. 27-36, it will be appreciated that the backside DTI structure 108 may alternatively extend into the first semiconductor substrate 0916 but not through the first semiconductor substrate 106 (e.g., as illustrated in FIG. 22 and FIG. 11).

As shown in cross-sectional view 2700 of FIG. 27, a dielectric layer 1218 is deposited over the backside 106b of the first semiconductor substrate 106 and over the backside DTI structure 108. In some embodiments, dielectric layer 1218 comprises silicon oxide, silicon nitride, or some other suitable material and is deposited by a CVD process, a PVD process, an ALD process, or some other suitable process.

As shown in cross-sectional view 2800 of FIG. 28, dielectric layer 1218 and the first semiconductor substrate 106 are etched to form grounding trenches 2802 in dielectric layer and the first semiconductor substrate 106. In some embodiments, a masking layer 2804 is formed over dielectric layer 1218 and the etching is performed according to the masking layer 2804. In some embodiments, the etching comprises a dry etching process or some other suitable process.

As shown in cross-sectional view 2900 of FIG. 29, a conductive layer 1210 is deposited over dielectric layer 1218 and lining the grounding trenches 2802 (e.g., on sidewalls and upper surfaces of the first semiconductor substrate 106, and on sidewalls of dielectric layer 1218). Further, a conductive layer 1212 is deposited over conductive layer 1210 and fills the grounding trenches 2802. In some embodiments, conductive layer 1210 comprises titanium nitride or some other suitable material and is deposited by a CVD process, a PVD process, an ALD process, or some other suitable process. In some embodiments, conductive layer 1212 comprises tungsten or some other suitable material and is deposited by a CVD process, a PVD process, an ALD process, or some other suitable process.

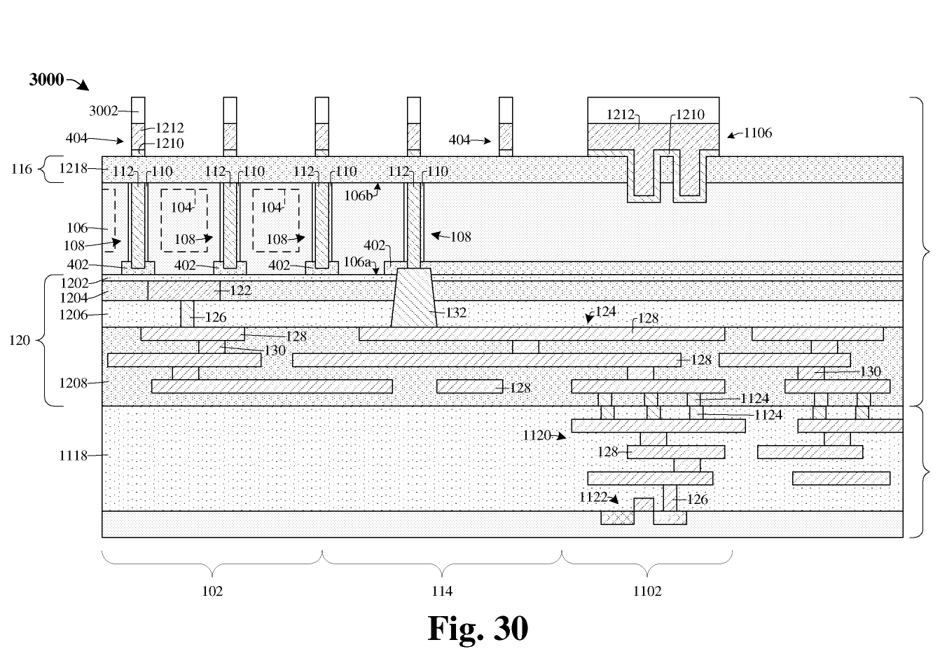

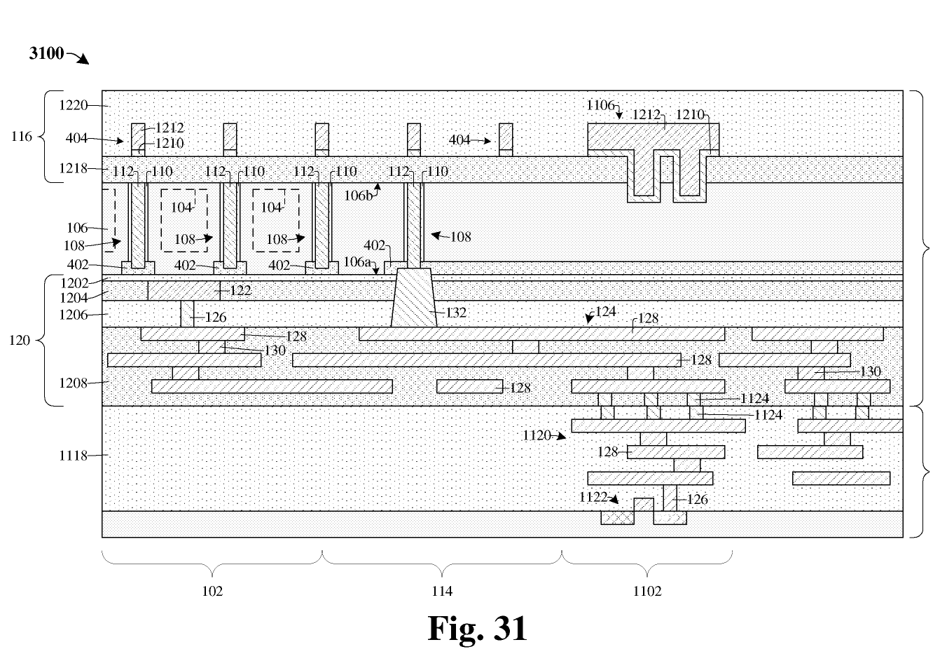

As shown in cross-sectional view 3000 of FIG. 30, conductive layer 1212 and conductive layer 1210 are etched to form (e.g., delimit) the conductive grid 404 and the backside grounding electrode 1106 from conductive layer 1212 and conductive layer 1210. In some embodiments, a masking layer 3002 is formed over conductive layer 1212 and the etching is performed according to the masking layer 3002. In some embodiments, the etching comprises a dry etching process or some other suitable process.

As shown in cross-sectional view 3100 of FIG. 31, a dielectric layer 1220 is deposited over the conductive grid 404, the backside grounding electrode 1106, and dielectric layer 1218. In some embodiments, dielectric layer 1220 comprises silicon oxide, silicon nitride, or some other suitable material and is deposited by a CVD process, a PVD process, an ALD process, or some other suitable process.

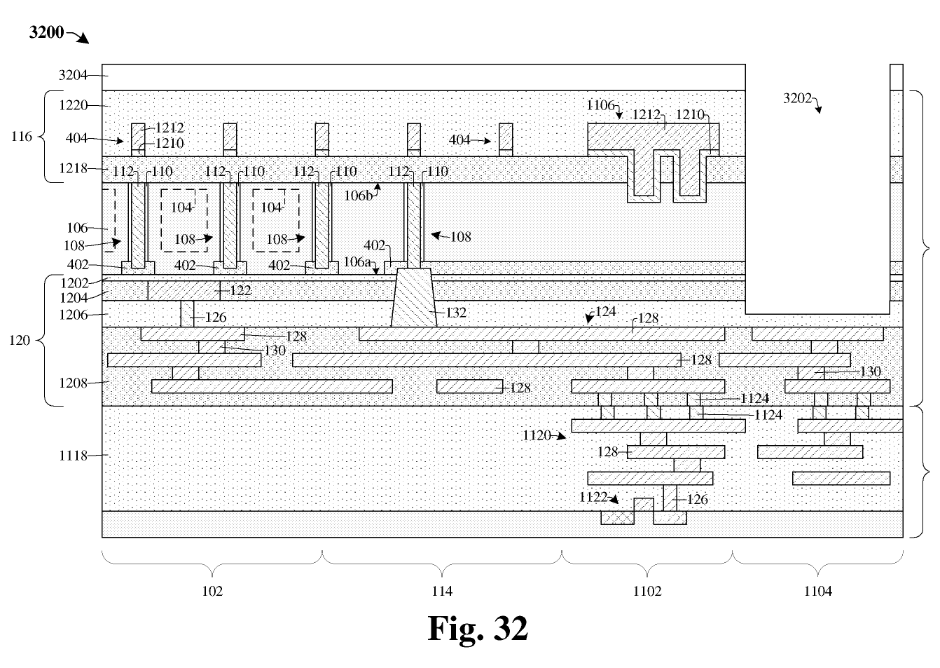

As shown in cross-sectional view 3200 of FIG. 32, dielectric structure 116 (e.g., dielectric layers 1220, 1218), the first semiconductor substrate 106, the frontside STI structure 402, and dielectric structure 120 (e.g., dielectric layers 1202, 1204, 1206) are etched to form a pad trench 3202 extending through dielectric structure 116, through the first semiconductor substrate 106, and into dielectric structure 120. In some embodiments, a masking layer 3204 is formed over dielectric layer 1220 and the etching is performed according to the masking layer 3204. In some embodiments, the etching comprises a dry etching process or some other suitable process.

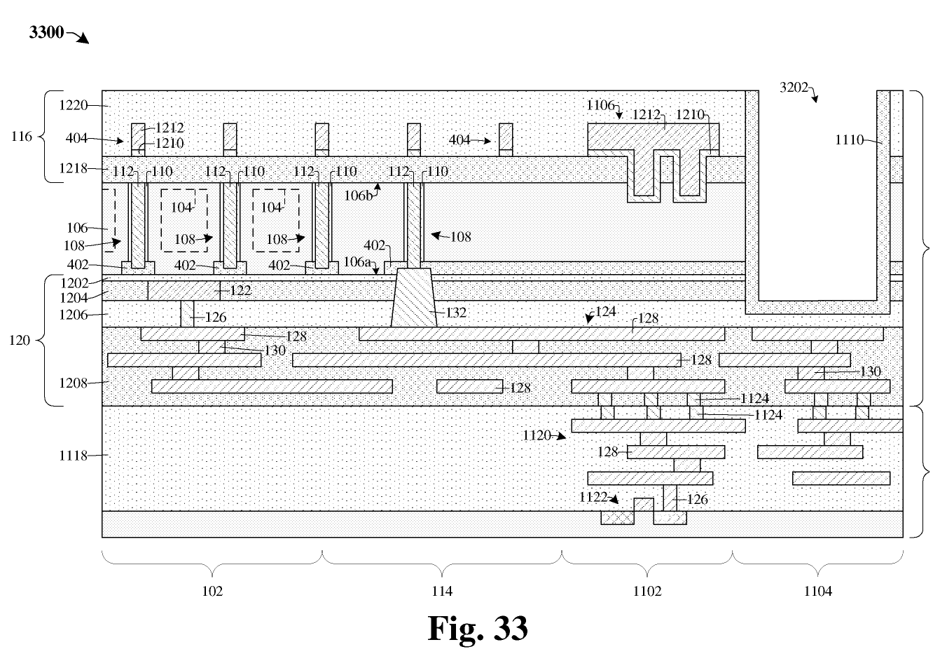

As shown in cross-sectional view 3300 of FIG. 33, a dielectric layer 1110 is deposited along the pad trench 3202 and lines the pad trench 3202 (e.g., is on sidewalls of dielectric structure 116, sidewalls of the first semiconductor substrate 106, and sidewalls of dielectric structure 120 that delimit the pad trench 3202). In some embodiments, dielectric layer 1110 comprises silicon oxide, silicon nitride, some high-k dielectric, or some other suitable material and is deposited by a CVD process, a PVD process, an ALD process, or some other suitable process.

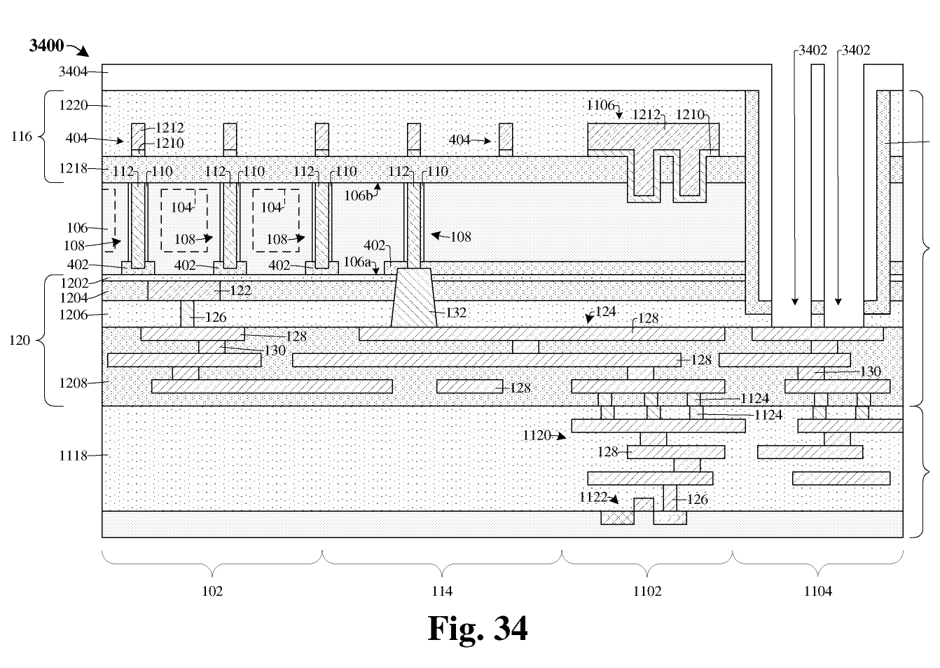

As shown in cross-sectional view 3400 of FIG. 34, dielectric layer 1110 and dielectric structure 120 are etched to form pad contact openings 3402 in dielectric layer 1110 and the dielectric structure 120 which uncover portions of a conductive line 128 of interconnect structure 124. In some embodiments, a masking layer 3404 is formed over dielectric layer 1220 and dielectric layer 1110, and the etching is performed according to the masking layer 3404. In some embodiments, the etching comprises a dry etching process or some other suitable process.

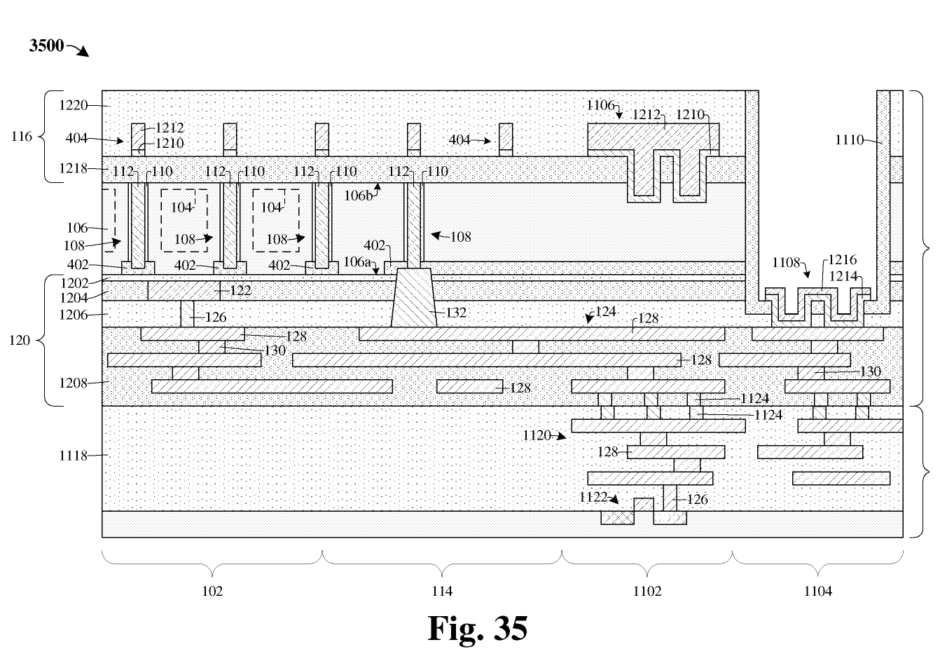

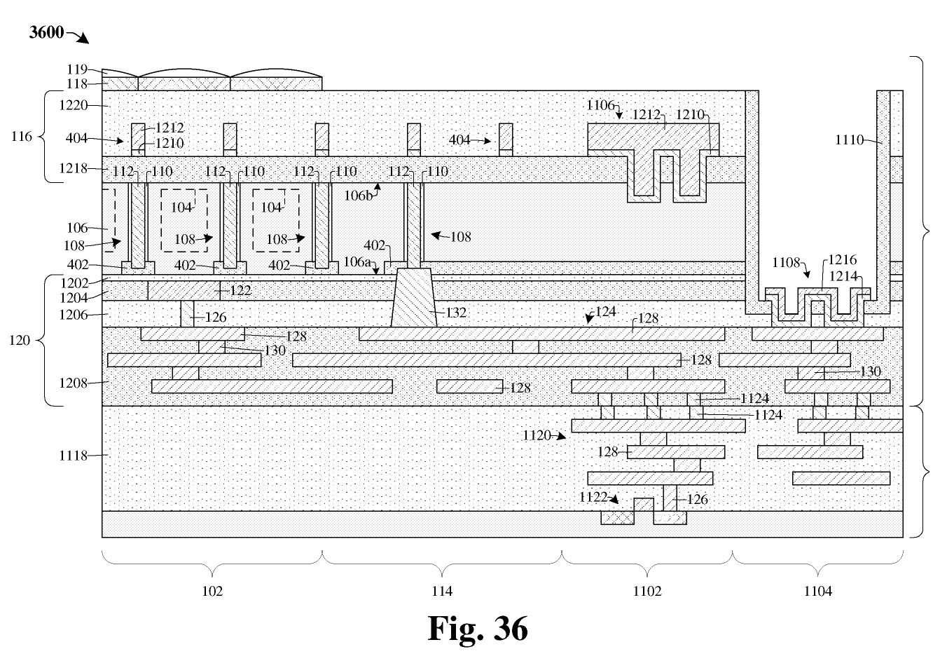

As shown in cross-sectional view 3500 of FIG. 35, a conductive pad 1108 is formed in the pad contact openings 3402 and on a conductive line 128 of interconnect structure 124. In some embodiments, forming the conductive pad 1108 comprises depositing a conductive pad layer 1214 in the pad contact openings 3402, depositing a conductive pad layer 1216 over conductive pad layer 1214, and etching conductive pad layer 1216 and conductive pad layer 1214 to form the conductive pad 1108 from conductive pad layer 1214 and conductive pad layer 1216. Conductive pad layer 1214 comprises a different conductor than conductive pad layer 1216. In some embodiments, conductive pad layer 1214 and/or conductive pad layer 1216 comprise tungsten, aluminum, titanium, titanium nitride, copper, or some other suitable material and are deposited by a CVD process, a PVD process, an ALD process, or some other suitable process.

As shown in cross-sectional view 3600 of FIG. 36, color filters 118 are formed over dielectric layer 1220 in the active pixel region 102. Further, micro lenses 119 are formed over the color filters 118.

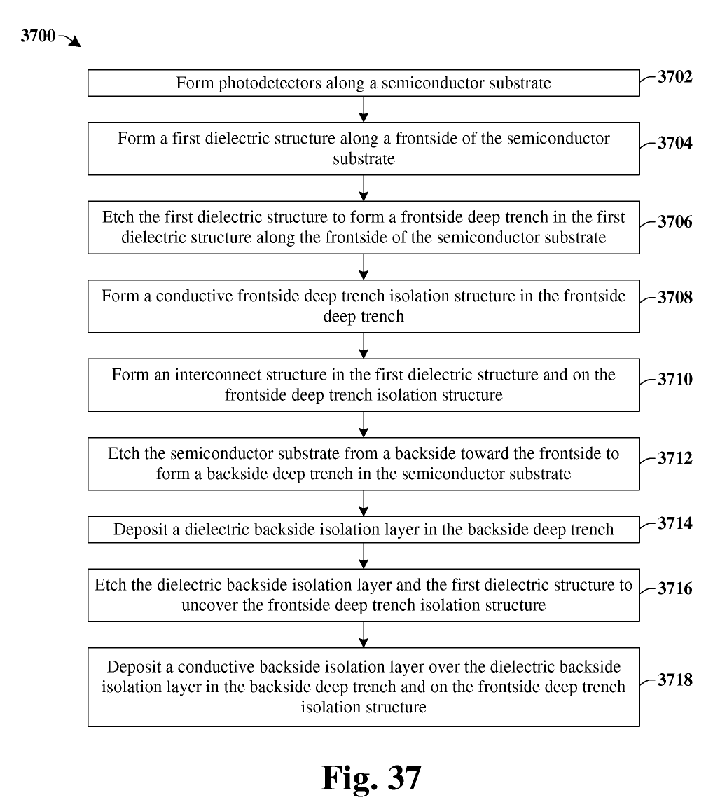

FIG. 37 illustrates a flow diagram of some embodiments of a method 3700 for forming an integrated chip including a frontside deep trench isolation structure which couples an interconnect structure to a backside deep trench isolation structure. While method 3700 is illustrated and described below as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

At block 3702, form photodetectors along a semiconductor substrate. FIG. 13 illustrates a cross-sectional view 1300 of some embodiments corresponding to block 3702.

At block 3704, form a first dielectric structure along a frontside of the semiconductor substrate. FIGS. 13-17 illustrate cross-sectional views 1300-1700 of some embodiments corresponding to block 3704.

At block 3706, etch the first dielectric structure to form a frontside deep trench in the first dielectric structure along the frontside of the semiconductor substrate. FIG. 15 illustrates a cross-sectional view 1500 of some embodiments corresponding to block 3706.

At block 3708, form a conductive frontside deep trench isolation structure in the frontside deep trench. FIG. 16 illustrates a cross-sectional view 1600 of some embodiments corresponding to block 3708.

At block 3710, form an interconnect structure in the first dielectric structure and on the frontside deep trench isolation structure. FIG. 17 illustrates a cross-sectional view 1700 of some embodiments corresponding to block 3710.

At block 3712, etch the semiconductor substrate from a backside toward the frontside to form a backside deep trench in the semiconductor substrate. FIGS. 18-19 illustrate cross-sectional views 1800-1900 of some embodiments corresponding to block 3712. FIG. 23 illustrates a cross-sectional view 2300 of some other embodiments corresponding to block 3712.

At block 3714, deposit a dielectric backside isolation layer in the backside deep trench. FIG. 20 illustrates a cross-sectional view 2000 of some embodiments corresponding to block 3714. FIG. 24 illustrates a cross-sectional view 2400 of some other embodiments corresponding to block 3714.

At block 3716, etch the dielectric backside isolation layer and the first dielectric structure to uncover the frontside deep trench isolation structure. FIG. 21 illustrates a cross-sectional view 2100 of some embodiments corresponding to block 3716. FIG. 25 illustrates a cross-sectional view 2500 of some other embodiments corresponding to block 3716.

At block 3718, deposit a conductive backside isolation layer over the dielectric backside isolation layer in the backside deep trench and on the frontside deep trench isolation structure. FIG. 22 illustrates a cross-sectional view 2200 of some embodiments corresponding to block 3718. FIG. 26 illustrates a cross-sectional view 2600 of some other embodiments corresponding to block 3718.

Thus, the present disclosure relates to an integrated chip and a method for forming the integrated chip, the integrated chip including a frontside DTI structure which couples an interconnect structure to a backside DTI structure.

Accordingly, in some embodiments, the present disclosure relates to an integrated chip including a first semiconductor substrate having a frontside and a backside opposite the frontside. A photodetector is within the first semiconductor substrate. A backside deep trench isolation (DTI) structure includes a conductive backside isolation layer and a dielectric backside isolation layer extending into the first semiconductor substrate from the backside toward the frontside and extending between the photodetector and neighboring photodetectors to isolate the photodetector from the neighboring photodetectors. The dielectric backside isolation layer is between the conductive backside isolation layer and the first semiconductor substrate. A first interconnect structure includes a first plurality of conductive interconnects along the frontside of the first semiconductor substrate. A conductive frontside DTI structure extends from the first interconnect structure to the conductive backside isolation layer and couples the conductive backside isolation layer to the first interconnect structure.

In other embodiments, the present disclosure relates to an integrated chip including a first semiconductor substrate having a frontside and a backside opposite the frontside. A photodetector is within the first semiconductor substrate. A first dielectric structure includes a first plurality of dielectric layers along the frontside of the first semiconductor substrate. A first interconnect structure includes a first plurality of conductive interconnects within the first dielectric structure. A conductive frontside deep trench isolation (DTI) structure is within the first dielectric structure, on a first conductive interconnect of the first interconnect structure, and coupled to the first interconnect structure. A backside DTI structure includes a conductive backside isolation layer and a dielectric backside isolation layer extending into the first semiconductor substrate from the backside toward the frontside. The dielectric backside isolation layer is between the conductive backside isolation layer and the first semiconductor substrate. A first portion of the conductive backside isolation layer extends between the photodetector and neighboring photodetectors to isolate the photodetector from the neighboring photodetectors. A second portion of the conductive backside isolation layer is laterally spaced from the photodetector and the neighboring photodetectors. The second portion extends through the first semiconductor substrate from the backside to the conductive frontside DTI structure and is coupled to the conductive frontside DTI structure.

In yet other embodiments, the present disclosure relates to a method for forming an integrated chip. The method includes forming a photodetector within a first semiconductor substrate. The first semiconductor substrate has a frontside and a backside opposite the frontside. The method includes depositing a first plurality of dielectric layers over the frontside of the first semiconductor substrate to form a first dielectric structure along the frontside of the first semiconductor substrate. The method includes etching the first dielectric structure to form a frontside deep trench in the first dielectric structure. The method includes depositing a conductive frontside isolation layer in the frontside deep trench to form a conductive frontside deep trench isolation (DTI) structure in the frontside deep trench. The method includes forming a first interconnect structure including a first plurality of conductive interconnects within the first dielectric structure and over the conductive frontside DTI structure. A first conductive line of the first interconnect structure is formed on the conductive frontside DTI structure. The method includes etching the first semiconductor substrate from the backside toward the frontside to form a backside deep trench in the first semiconductor substrate. The method includes depositing a dielectric backside isolation layer in the backside deep trench. The method includes etching the dielectric backside isolation layer and the first dielectric structure along a bottom of the backside deep trench to extend the backside deep trench into first dielectric structure and to uncover a portion of the conductive frontside DTI structure. The method includes depositing a conductive backside isolation layer over the dielectric backside isolation layer, in the backside deep trench, and on the conductive frontside DTI structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated chip comprising:
a first semiconductor substrate having a frontside and a backside opposite the frontside;
a photodetector within the first semiconductor substrate;
a backside deep trench isolation (DTI) structure comprising a conductive backside isolation layer and a dielectric backside isolation layer extending into the first semiconductor substrate from the backside toward the frontside and extending between the photodetector and neighboring photodetectors to isolate the photodetector from the neighboring photodetectors, the dielectric backside isolation layer between the conductive backside isolation layer and the first semiconductor substrate;
a first interconnect structure comprising a first plurality of conductive interconnects along the frontside of the first semiconductor substrate; and
a conductive frontside DTI structure extending from the first interconnect structure to the conductive backside isolation layer and coupling the conductive backside isolation layer to the first interconnect structure.

2. The integrated chip of claim 1, wherein a bias circuit is coupled to the conductive backside isolation layer through the first interconnect structure and the conductive frontside DTI structure.

3. The integrated chip of claim 1, further comprising:
a second interconnect structure comprising a second plurality of conductive interconnects under the first interconnect structure and coupled to the first interconnect structure; and
a second semiconductor substrate under the second interconnect structure; and
a bias circuit along the second semiconductor substrate, the bias circuit coupled to the conductive backside isolation layer through the second interconnect structure, the first interconnect structure, and the conductive frontside DTI structure.

4. The integrated chip of claim 1, wherein the photodetector is in an active pixel region, wherein the conductive frontside DTI structure is in a dummy pixel region that is beside the active pixel region, wherein the backside DTI structure is in the active pixel region and the dummy pixel region, and wherein the conductive backside isolation layer contacts the conductive frontside DTI structure in the dummy pixel region.

5. The integrated chip of claim 1, wherein between the photodetector and the neighboring photodetectors, the first semiconductor substrate extends directly under the backside DTI structure, and wherein directly over the conductive frontside DTI structure, the backside DTI structure extends through the first semiconductor substrate to an upper surface of the conductive frontside DTI structure.

6. The integrated chip of claim 1, wherein between the photodetector and the neighboring photodetectors, the backside DTI structure extends through the first semiconductor substrate to a dielectric layer that is along the frontside of the first semiconductor substrate, and wherein directly over the conductive frontside DTI structure, the backside DTI structure extends through the first semiconductor substrate and through the dielectric layer to an upper surface of the conductive frontside DTI structure.

7. The integrated chip of claim 1, further comprising:
a dielectric frontside shallow trench isolation (STI) structure extending into the first semiconductor substrate from the frontside toward the backside directly under the backside DTI structure, wherein the conductive frontside DTI structure extends into the dielectric frontside STI structure from below the frontside STI structure, and wherein the backside DTI structure extends into the frontside STI structure directly over the conductive frontside DTI structure.

8. The integrated chip of claim 1, wherein the backside DTI structure is on a top surface of the conductive frontside DTI structure and extends below the top surface of the conductive frontside DTI structure along an outer sidewall of the conductive frontside DTI structure.

9. The integrated chip of claim 1, wherein the backside DTI structure extends into the conductive frontside DTI structure below a top surface of the conductive frontside DTI structure, and wherein the backside DTI structure is between a pair of inner sidewalls of the conductive frontside DTI structure and on an upper surface of the conductive frontside DTI structure that is below the top surface of the conductive frontside DTI structure.

10. The integrated chip of claim 1, wherein backside DTI structure extends into the conductive frontside DTI structure below a top surface of the conductive frontside DTI structure, the backside DTI structure is on an upper surface of the conductive frontside DTI structure that is below the top surface of the conductive frontside DTI structure, and the backside DTI structure extends along an outer sidewall of the conductive frontside DTI structure.

11. The integrated chip of claim 1, wherein the conductive frontside DTI structure is a first conductive frontside DTI structure, the integrated chip further comprising:
a second conductive frontside DTI structure laterally spaced from first conductive frontside DTI structure and extending from the first interconnect structure to the conductive backside isolation layer.

12. An integrated chip comprising:
a first semiconductor substrate having a frontside and a backside opposite the frontside;
a photodetector within the first semiconductor substrate;
a first dielectric structure comprising a first plurality of dielectric layers along the frontside of the first semiconductor substrate;
a first interconnect structure comprising a first plurality of conductive interconnects within the first dielectric structure;
a conductive frontside deep trench isolation (DTI) structure within the first dielectric structure, on a first conductive interconnect of the first interconnect structure, and coupled to the first interconnect structure; and
a backside DTI structure comprising a conductive backside isolation layer and a dielectric backside isolation layer extending into the first semiconductor substrate from the backside toward the frontside, the dielectric backside isolation layer between the conductive backside isolation layer and the first semiconductor substrate, a first portion of the conductive backside isolation layer extending between the photodetector and neighboring photodetectors to isolate the photodetector from the neighboring photodetectors, a second portion of the conductive backside isolation layer laterally spaced from the photodetector and the neighboring photodetectors, the second portion extending through the first semiconductor substrate from the backside to the conductive frontside DTI structure and coupled to the conductive frontside DTI structure.

13. The integrated chip of claim 12, further comprising:
a conductive grid spaced over the backside DTI structure;
a color filter spaced over the conductive grid;
a micro lens over the color filter;
a backside grounding electrode beside the conductive grid, coupled to the conductive grid, and laterally spaced from the conductive frontside DTI structure; and
a conductive pad along the frontside of the first semiconductor substrate and laterally spaced from the backside grounding electrode.

14. The integrated chip of claim 13, further comprising:
a second semiconductor substrate spaced under the first semiconductor substrate;
a bias circuit along the second semiconductor substrate; and
a second interconnect structure comprising a second plurality of conductive interconnects between the second semiconductor substrate and the first interconnect structure and coupled to the first interconnect structure such that the bias circuit is coupled to the conductive backside isolation layer through the second interconnect structure, the first interconnect structure, and the conductive frontside DTI structure.

15. The integrated chip of claim 12, wherein a top surface of the conductive frontside DTI structure is above the frontside of the first semiconductor substrate and spaced directly under the first semiconductor substrate.

16. A method for forming an integrated chip, the method comprising:
forming a photodetector within a first semiconductor substrate, the first semiconductor substrate having a frontside and a backside opposite the frontside;
depositing a first plurality of dielectric layers over the frontside of the first semiconductor substrate to form a first dielectric structure along the frontside of the first semiconductor substrate;
etching the first dielectric structure to form a frontside deep trench in the first dielectric structure;
depositing a conductive frontside isolation layer in the frontside deep trench to form a conductive frontside deep trench isolation (DTI) structure in the frontside deep trench;
forming a first interconnect structure comprising a first plurality of conductive interconnects within the first dielectric structure and over the conductive frontside DTI structure, wherein a first conductive line of the first interconnect structure is formed on the conductive frontside DTI structure;
etching the first semiconductor substrate from the backside toward the frontside to form a backside deep trench in the first semiconductor substrate;
depositing a dielectric backside isolation layer in the backside deep trench;
etching the dielectric backside isolation layer and the first dielectric structure along a bottom of the backside deep trench to extend the backside deep trench into first dielectric structure and to uncover a portion of the conductive frontside DTI structure; and
depositing a conductive backside isolation layer over the dielectric backside isolation layer, in the backside deep trench, and on the conductive frontside DTI structure.

17. The method of claim 16, further comprising:
forming a gate electrode along the frontside of the first semiconductor substrate;
etching the first dielectric structure to form a contact opening over the gate electrode; and
depositing the conductive frontside isolation layer in the contact opening and on the gate electrode.

18. The method of claim 16, further comprising:
etching the first semiconductor substrate from the frontside toward the backside to form a frontside shallow trench in the first semiconductor substrate; and
depositing a dielectric frontside isolation layer in the frontside shallow trench to form a frontside shallow trench isolation (STI) structure in the frontside shallow trench, wherein the frontside STI structure is part of the first dielectric structure, wherein the frontside deep trench is formed in the frontside STI structure, and wherein the backside deep trench is formed in the frontside STI structure.

19. The method of claim 16, wherein the etching the first semiconductor substrate from the backside toward the frontside to form the backside deep trench in the first semiconductor substrate comprises:
performing a first etching process into the first semiconductor substrate from the backside to the frontside such that the backside deep trench extends through the first semiconductor substrate to the first dielectric structure.

20. The method of claim 16, wherein the etching the first semiconductor substrate from the backside toward the frontside to form the backside deep trench in the first semiconductor substrate comprises:
performing a first etching process into the first semiconductor substrate from the backside toward the frontside to form the backside deep trench in the first semiconductor substrate between the photodetector and neighboring photodetectors and directly over the conductive frontside DTI structure; and
performing a second etching process into the first semiconductor substrate directly over the conductive frontside DTI structure to extend the backside deep trench through the first semiconductor substrate to the first dielectric structure.
